(19) United States
(12) Patent Application Publication
(10) Pub. No.: US 2026/0247698 A1
(43) Pub. Date: Aug. 20, 2026

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Cheng-Ting CHUNG, Hsinchu City (TW); Hou-Yu CHEN, Zhubei City (TW); Jin CAI, Hsinchu City (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 19/220,538

(22) Filed: May 28, 2025

Related U.S. Application Data
(60) Provisional application No. 63/759,756, filed on Feb. 18, 2025.

(51) Int. Cl. H10D 84/83; H10D 30/00; H10D 30/01; H10D 30/43; H10D 62/10; H10D 62/13; H10D 64/01; H10D 64/27; H10D 84/01

(52) U.S. Cl. CPC H10D 84/832; H10D 30/014; H10D 30/0191; H10D 30/43; H10D 30/502; H10D 62/121; H10D 62/151; H10D 64/017; H10D 64/021; H10D 64/518; H10D 84/0147

(57) ABSTRACT

Semiconductor structures and methods for forming the same are provided. The semiconductor structure includes a plurality of nanostructures formed over a substrate, and an isolation structure formed over the substrate. The semiconductor structure includes a gate structure formed on the nanostructures, and the gate structure includes a gate dielectric layer and a metal layer over the gate dielectric layer. The semiconductor structure includes a first gate spacer layer formed on a sidewall of the gate structure, and a dielectric constant of the gate dielectric layer is greater than a dielectric constant of the first gate spacer layer. The gate structure includes a first portion on the isolation structure and a second portion below a topmost nanostructure, and the first portion has a first gate length, the second portion has a second gate length, and the first gate length is greater than the second gate length.

### CROSS REFERENCE TO RELATED APPLICATIONS

This Application claims the benefit of U.S. Provisional Application No. 63/759,756 filed on Feb. 18, 2025, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A-1 to 2G-1 illustrate cross-sectional representations of various stages of manufacturing the semiconductor structure shown along line A-A′ in FIG. 1E in accordance with some embodiments.

FIGS. 2A-2 to 2G-2 illustrate cross-sectional representations of various stages of manufacturing the semiconductor structure shown along line B-B′ in FIG. 1E in accordance with some embodiments.

FIGS. 2A-3 to 2G-3 illustrate cross-sectional representations of various stages of manufacturing the semiconductor structure shown along line C-C′ in FIG. 1E in accordance with some embodiments

FIG. 3 shows a top view of the semiconductor structure along line DD′ of FIG. 2G-2, in accordance with some embodiments.

FIGS. 4A-1-4I-1 illustrate cross-sectional representations of a semiconductor structure shown along line A-A′ in FIG. 1E, in accordance with some embodiments.

FIGS. 4A-2 to 4I-2 illustrate cross-sectional representations of various stages of manufacturing a semiconductor structure shown along line B-B′ in FIG. 1E, in accordance with some embodiments.

FIGS. 4A-3 to 4I-3 illustrate cross-sectional representations of various stages of manufacturing a semiconductor structure shown along line C-C′ in FIG. 1E, in accordance with some embodiments.

FIG. 5 shows a top view of the semiconductor structure along line DD′ of FIG. 4I-2, in accordance with some embodiments.

FIGS. 6A-1-6D-1 illustrate cross-sectional representations of a semiconductor structure, shown along line A-A′ in FIG. 1E, in accordance with some embodiments.

FIGS. 6A-2-6D-2 illustrate cross-sectional representations of a semiconductor structure, shown along line B-B′ in FIG. 1E, in accordance with some embodiments.

FIGS. 6A-3-6D-3 illustrate cross-sectional representations of a semiconductor structure, shown along line C-C′ in FIG. 1E, in accordance with some embodiments.

FIG. 7 shows a top view of a semiconductor structure along line DD′ of FIG. 6D-2, in accordance with some embodiments.

FIGS. 8A-1, 8A-2 and 8A-3 illustrate cross-sectional representations of a semiconductor structure, in accordance with some embodiments.

FIGS. 9A-1, 9A-2 and 9A-3 illustrate cross-sectional representations of a semiconductor structure, in accordance with some embodiments.

FIGS. 10A-1, 10A-2 and 10A-3 illustrate cross-sectional representations of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structure includes an isolation structure formed over a substrate. A number of nanostructures (channel layers) are formed over the substrate. A gate structure is formed on the nanostructures, and a gate spacer layer formed on a sidewall of the gate structure. The gate structure includes a first portion (or outer gate), a second portion (or inner gate) and a third portion. The first portion is formed over the topmost nanostructure, a second portion is below the topmost nanostructure, and a third portion is formed on the isolation structure. The first portion (or outer gate) has a first gate length, the second portion (or inner gate) has a second gate length, and the third portion has a third gate length. The first gate length of the first portion (or outer gate) is greater than the second gate length of the second portion (or inner gate), and the third gate length is greater than the second gate length. Therefore, the risk of a void or seam forming in the second portion (or inner gate) of the gate structure is reduced and the performance of the semiconductor structure is improved.

The source/drain (S/D) structures or S/D region(s) may refer to a source or a drain, individually or collectively dependent upon the context.

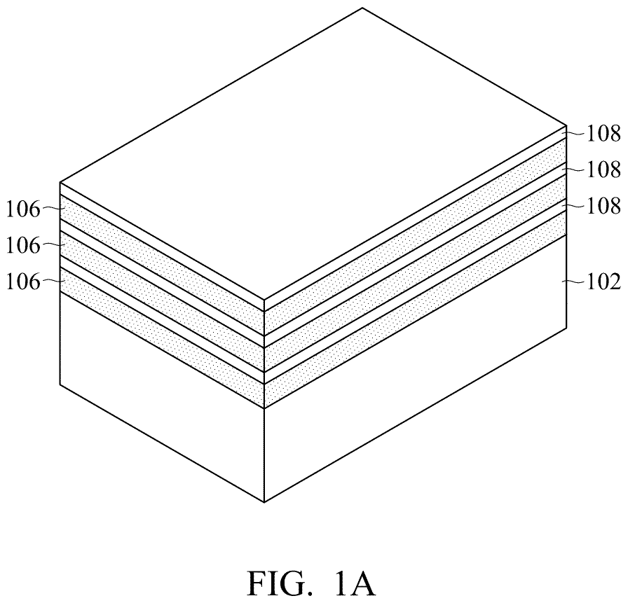

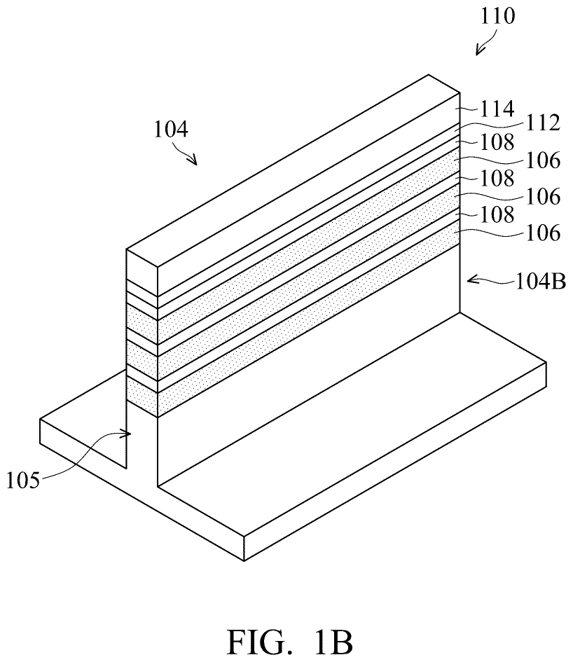

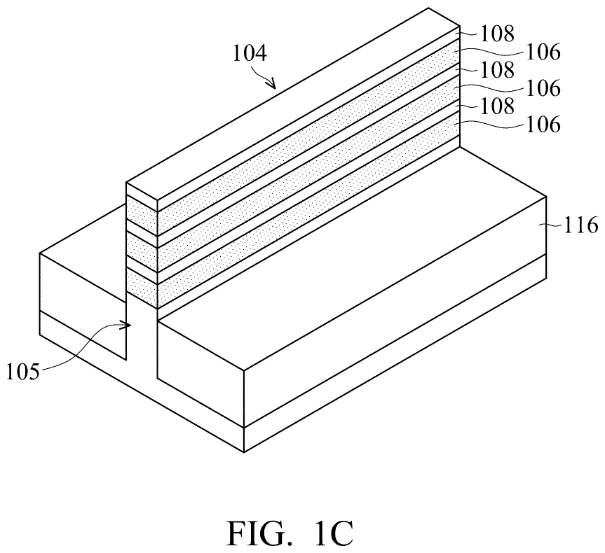

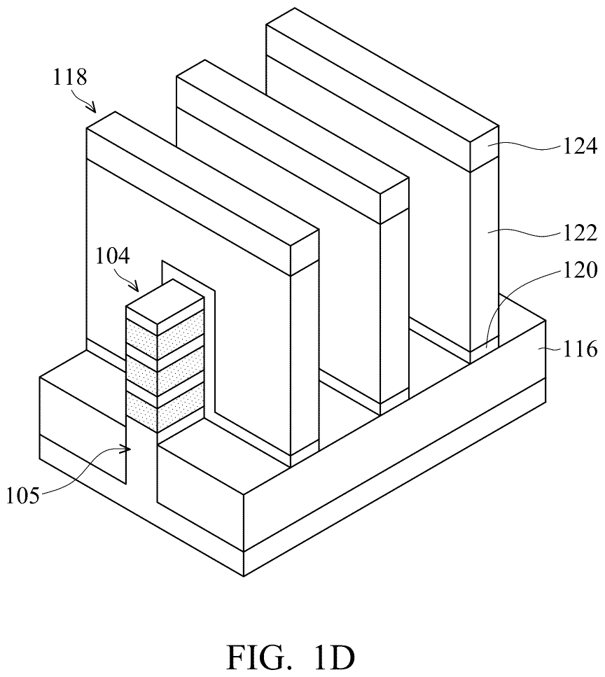

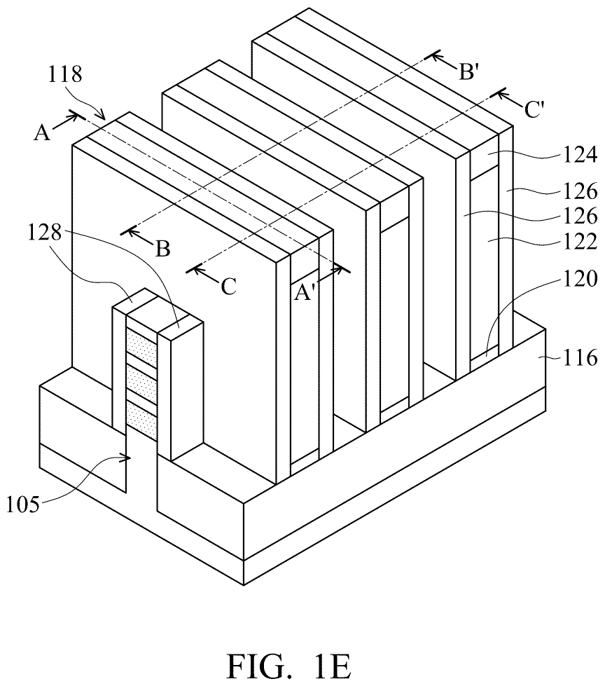

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

As shown in FIG. 1B, after the first semiconductor material layers 106 and the second semiconductor material layers 108 are formed as a semiconductor material stack over the substrate 102, the semiconductor material stack is patterned to form a fin structure 104, in accordance with some embodiments. In some embodiments, the fin structure 104 includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

As shown in FIG. 1C, after the fin structure 104 is formed, an isolation structure 116 is formed around the fin structure 104, and the mask structure 110 is removed, in accordance with some embodiments. The isolation structure 116 is configured to electrically isolate active regions (e.g. the fin structure 104) of the semiconductor structure 100a and is also referred to as shallow trench isolation (STI) feature in accordance with some embodiments. The top surface of the base fin structure 105 is higher than the top surface of the isolation structure 116.

The isolation structure 116 may be formed by depositing an insulating layer over the substrate 102 and recessing the insulating layer so that the fin structure 104 is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

As shown in FIG. 1D, after the isolation structure 116 is formed, dummy gate structures 118 are formed across the fin structure 104 and extend over the isolation structure 116, in accordance with some embodiments. The dummy gate structures 118 may be used to define the source/drain (S/D) regions and the channel regions of the resulting semiconductor structure 100a. The top surface of the base fin structure 105 is higher than the top surface of the isolation structure 116.

In some embodiments, the dummy gate structures 118 include dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

As shown in FIG. 1E, after the dummy gate structures 118 are formed, gate spacer layer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain (S/D) structures from the dummy gate structure 118 and support the dummy gate structure 118, and the fin spacer layers 128 may be configured to constrain a lateral growth of subsequently formed source/drain structure and support the fin structure 104.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

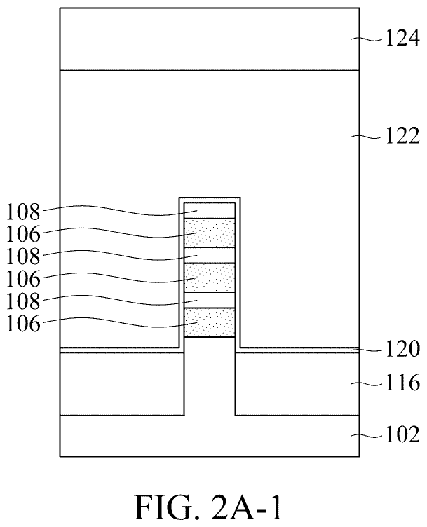

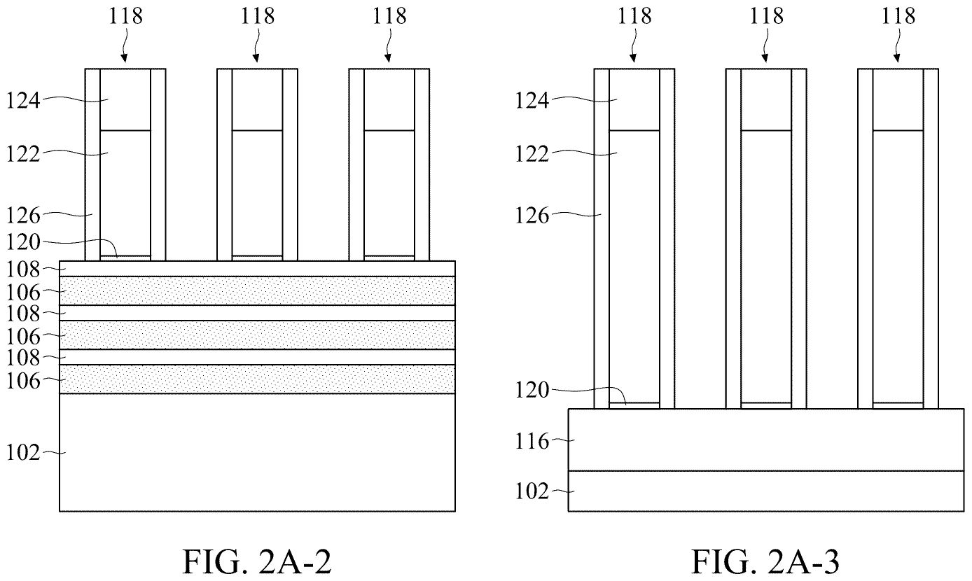

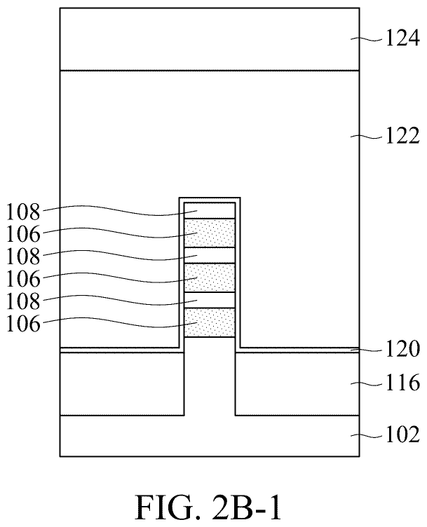

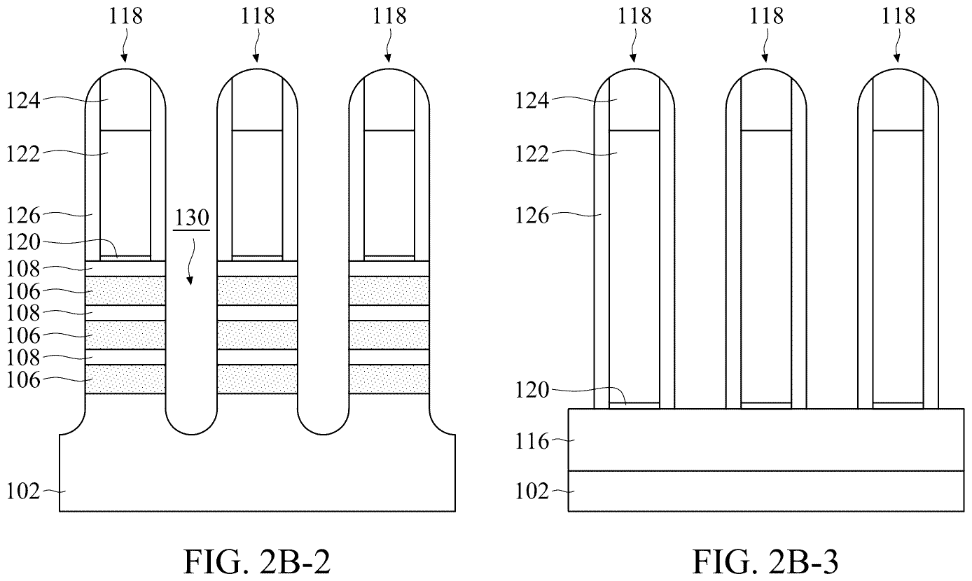

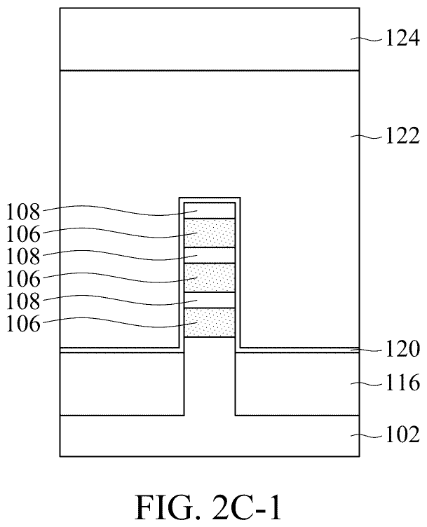

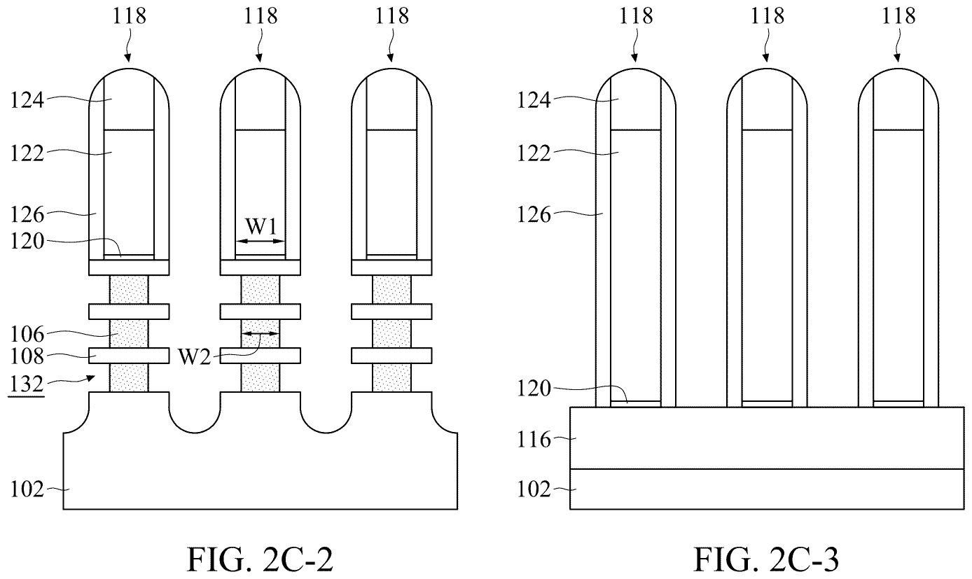

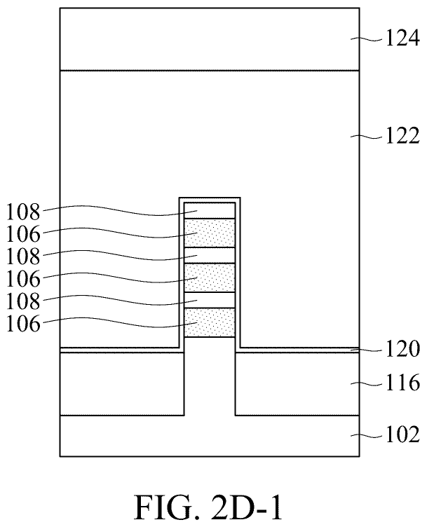

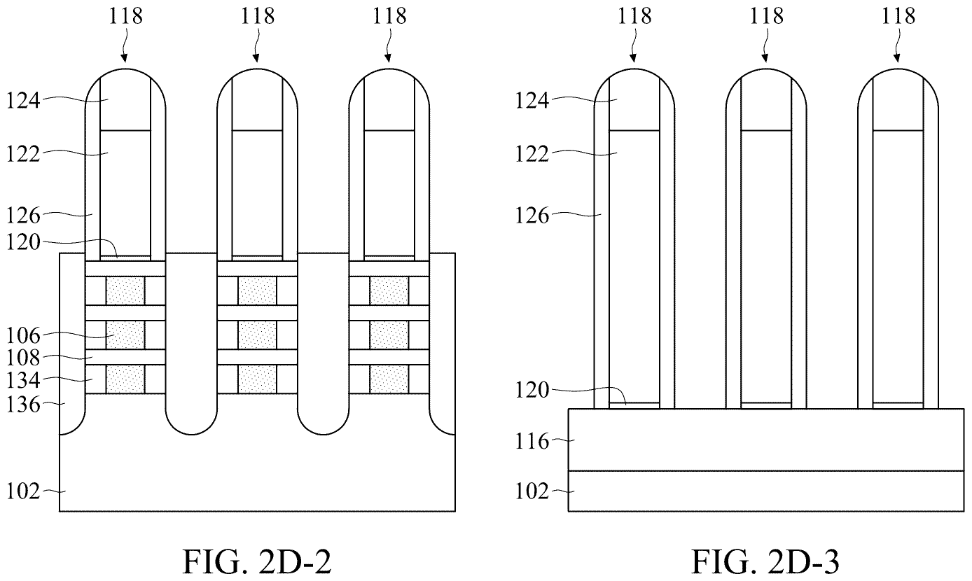

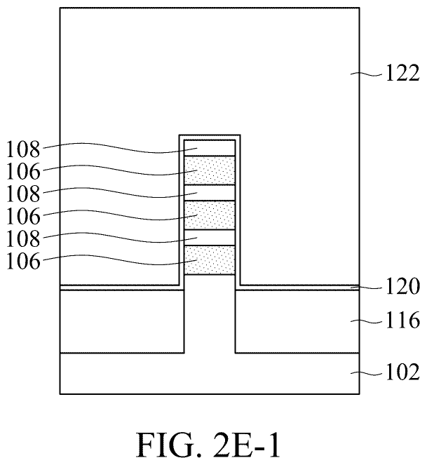

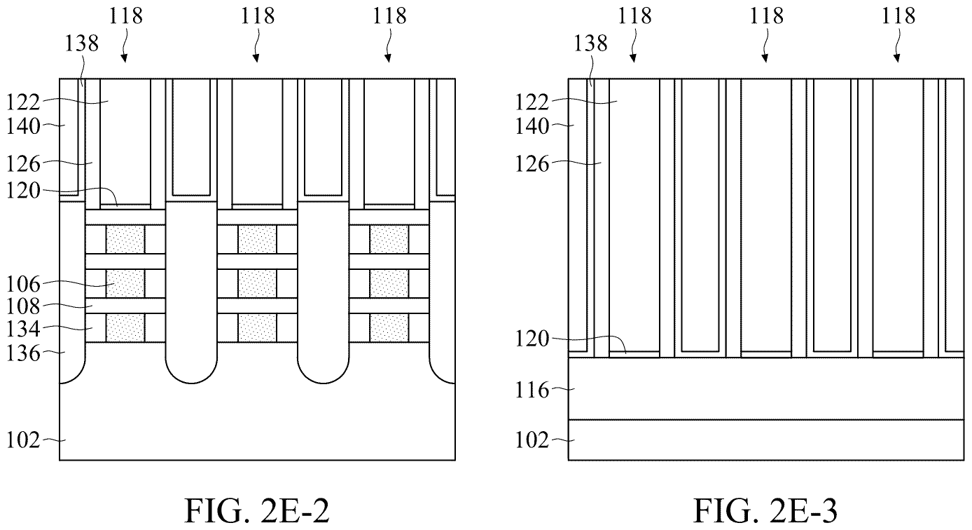

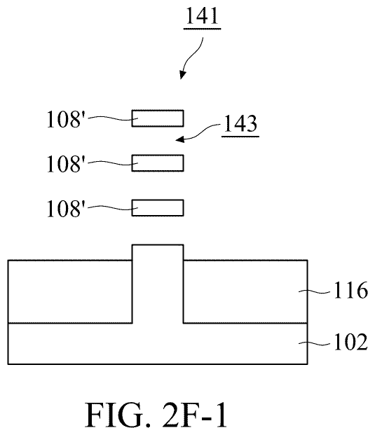

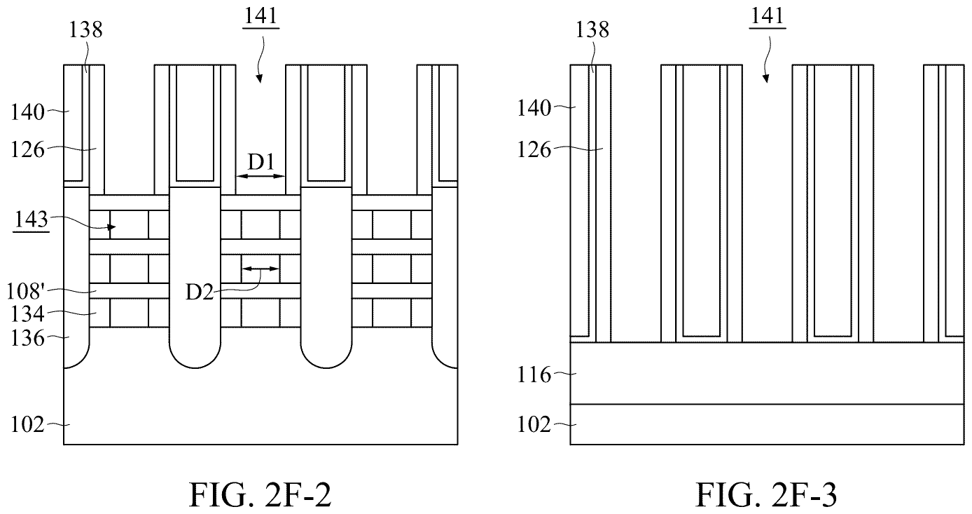

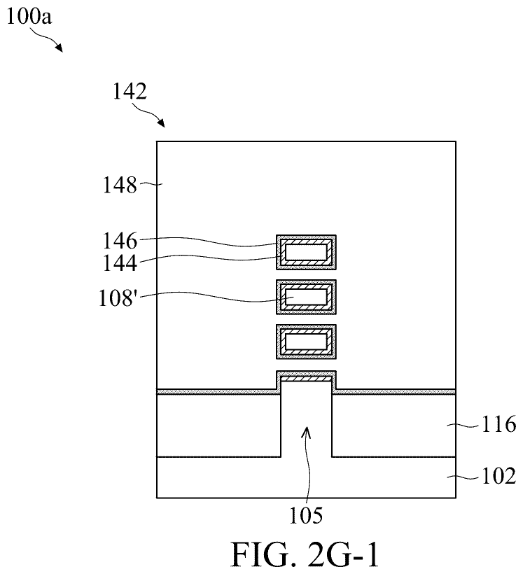

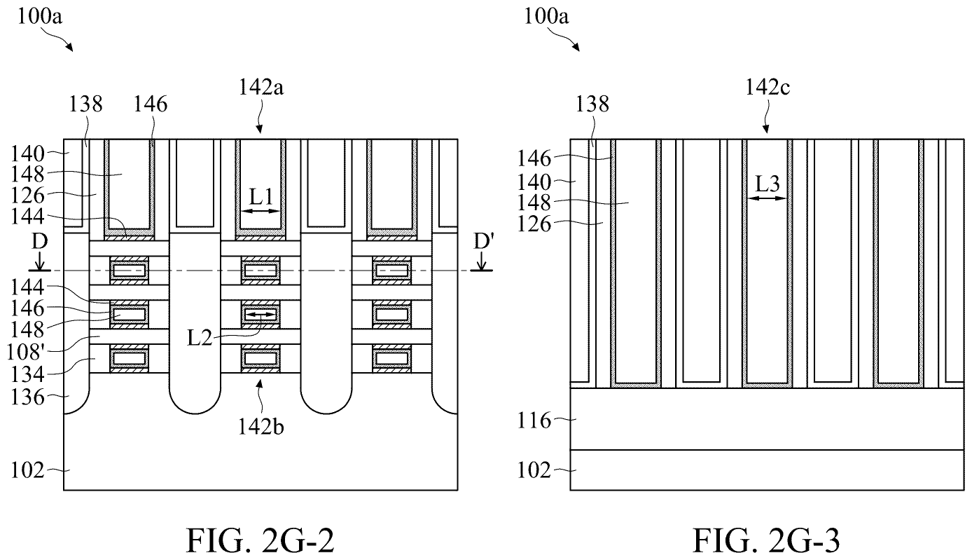

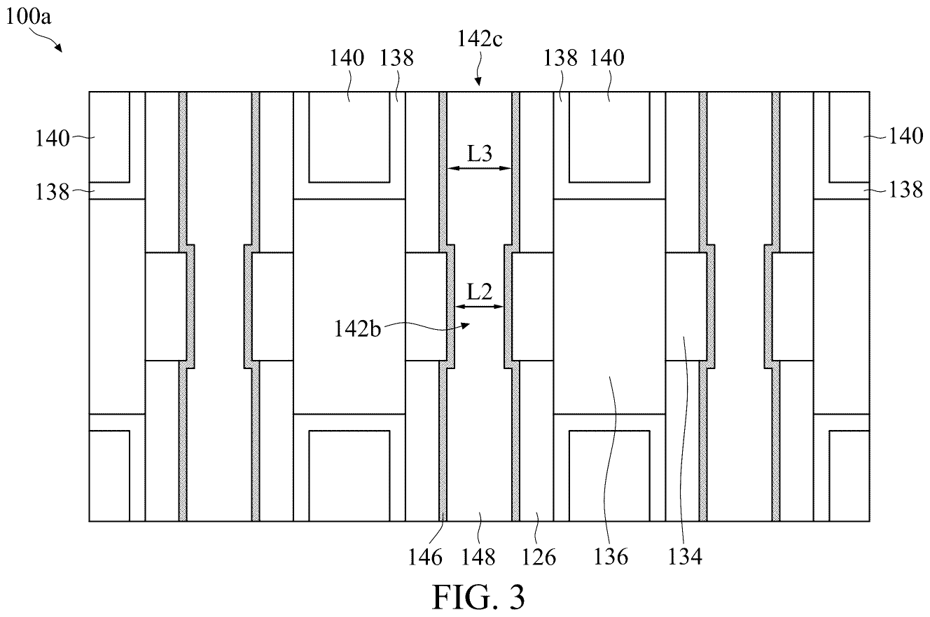

FIGS. 2A-1 to 2G-1 illustrate cross-sectional representations of various stages of manufacturing the semiconductor structure 100a shown along line A-A′ in FIG. 1E in accordance with some embodiments. FIGS. 2A-2 to 2G-2 illustrate cross-sectional representations of various stages of manufacturing the semiconductor structure 100a shown along line B-B′ in FIG. 1E in accordance with some embodiments. FIGS. 2A-3 to 2G-3 illustrate cross-sectional representations of various stages of manufacturing the semiconductor structure 100a shown along line C-C′ in FIG. 1E in accordance with some embodiments.

More specifically, FIG. 2A-1 illustrates a cross-sectional representation of the semiconductor structure 100a shown along line A-A′ in FIG. 1E, in accordance with some embodiments. FIGS. 2A-2 illustrates a cross-sectional representation of the semiconductor structure 100b shown along line B-B′ in FIG. 1E, in accordance with some embodiments. FIGS. 2A-3 illustrates a cross-sectional representation of the semiconductor structure 100c shown along line C-C′ in FIG. 1E, in accordance with some embodiments.

As shown in FIGS. 2A-1 and 2A-2, the dummy gate structures 118 are formed, and the gate spacer layers 126 are formed on opposite sidewall surfaces of the dummy gate structures 118.

As shown in FIG. 2A-3, the dummy gate structures 118 are formed on the isolation structure 116. The gate spacer layers 126 are formed over the isolation structure 116.

As shown in FIGS. 2B-1, 2B-2, and 2B-3, after the gate spacer layers 126 and the fin spacer layers 128 are formed, the source/drain (S/D) regions of the fin structure 104 are recessed to form source/drain (S/D) trenches 130, as shown in in accordance with some embodiments.

More specifically, a portion of the first semiconductor material layers 106 and a portion of the second semiconductor material layers 108 not covered by the dummy gate structures 118 and the gate spacer layers 126 are removed. The bottom surface of the S/D trench 130 in lower than the top surface of the bottommost first semiconductor material layer 106.

In some embodiments, the fin structure 104 is recessed by performing an etching process. The etching process may be an anisotropic etching process, such as dry plasma etching, and the dummy gate structure 118 and the gate spacer layers 126 are used as etching masks during the etching process.

Afterwards, as shown in FIGS. 2C-1, 2C-2 and 2C-3, after the source/drain (S/D) trenches 130 are formed, the first semiconductor material layers 106 exposed by the source/drain (S/D) recesses 130 are laterally recessed to form notches 132, in accordance with some embodiments.

In some embodiments, an etching process is performed on the semiconductor structure 100a to laterally recess the first semiconductor material layers 106 of the fin structure 104 from the source/drain (S/D) recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

The dummy gate structure 118 has the first width W1, and the remaining first semiconductor material layer 106 has the second width W2 after the etching process. In some embodiments, the first width W1 of the dummy gate structure 118 is greater than the second width W2 of the remaining first semiconductor material layer 106. More specifically, the inner sidewall surface of the gate spacer layer 126 is not aligned with the sidewall surface of the remaining first semiconductor material layer 106. The inner sidewall surface of the gate spacer layer 126 extends beyond the sidewall surface of the remaining first semiconductor material layer 106. In other words, the interface between the gate spacer layer 126 and the gate electrode layer 122 is not aligned with the sidewall surface of the remaining first semiconductor material layer 106. The interface between the gate spacer layer 126 and the gate electrode layer 122 extends beyond the sidewall surface of the remaining first semiconductor material layer 106.

Next, as shown in FIGS. 2D-1, 2D-2 and 2D-3, the inner spacer layers 134 are formed in the notches 132 between the second semiconductor material layers 108, in accordance with some embodiments. The inner spacer layers 134 are configured to separate the source/drain (S/D) structures and the gate structures formed in subsequent manufacturing processes in accordance with some embodiments.

In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

After the inner spacer layers 134 are formed, the source/drain (S/D) structures 136 are formed in the S/D recesses 130, in accordance with some embodiments. The top surface of the S/D structure 136 is higher than the top surface of the fin structure 104. The top surface of the S/D structure 136 is higher than the bottom surface of the gate spacer layer 126.

In some embodiments, the source/drain (S/D) structures 136 are epitaxial structures. In some embodiments, the source/drain (S/D) structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structures 136 are made of any applicable material, such as Ge, Si, GaAs, AlGaAs, SiGe, GaAsP, SiP, SiC, SiCP, or a combination thereof.

In some embodiments, the first source/drain (S/D) structures 136 are in-situ doped during the epitaxial growth process. For example, the source/drain (S/D) structures 136 may be the epitaxially grown SiGe doped with boron (B). For example, the source/drain (S/D) structures 136 may be the epitaxially grown Si doped with carbon to form silicon: carbon (Si:C) source/drain features, phosphorous to form silicon: phosphor (Si:P) source/drain features, or both carbon and phosphorous to form silicon carbon phosphor (SiCP) source/drain features. In some embodiments, the source/drain (S/D) structures 136 are doped in one or more implantation processes after the epitaxial growth process.

Afterwards, as shown in FIGS. 2E-1, 2E-2 and 2E-3, after the source/drain (S/D) structures 136 are formed, a contact etch stop layer (CESL) 138 is conformally formed to cover the S/D structures 136 and an interlayer dielectric (ILD) layer 140 is formed over the contact etch stop layers 138, in accordance with some embodiments. As a result, the interface between the S/D structure 16 and the CESL 138 is higher than the top surface of the fin structure 104. The interface between the S/D structure 16 and the CESL 138 is higher than bottom surface of the gate spacer layer 126.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), or another applicable low-k dielectric material. The ILD layer 140 may be formed by chemical vapor deposition (CVD), physical vapor deposition, (PVD), atomic layer deposition (ALD), or another applicable process.

After the contact etch stop layer 138 and the ILD layer 140 are deposited, a planarization process such as CMP or an etch-back process may be performed until the gate electrode layers 120 of the dummy gate structures 118 are exposed, as shown in FIG. 2E-2 in accordance with some embodiments.

Next, as shown in FIGS. 2F-1, 2F-2 and 2F-3, the dummy gate structure 118 is removed to form an outer trench 141, in accordance with some embodiments. As a result, the fin structure 104 are exposed by the outer trench 141.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using plasma dry etching, dry chemical etching, and/or wet etching.

Next, the first semiconductor material layers 106 of the fin structure 104 are removed to form a number of inner trenches 143, in accordance with some embodiments. The nanostructures 108′ with the second semiconductor material layers 108 are formed. The nanostructures 108′ are used as the channel layers of the semiconductor structure 100a. The S/D structures 136 are attached to the nanostructures 108′ (or channel layers). The fin structure 104 includes the nanostructures 108′.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

It should be noted that, as shown in FIG. 2F-2, the outer trench 141 has a first width D1, and the inner trench 143 has a second width D2. The first width D1 of the outer trench 141 is greater than the second width D2 of the inner trench 143 since the first width W1 of the dummy gate structure 118 is greater than the second width W2 of the remaining first semiconductor material layer 106 (shown in FIG. 2C-2).

The two adjacent gate spacer layers 126 has the first width D1, and the two adjacent inner spacer layers 134 has the second width D2. The first width D1 is greater than the second width D2.

Next, as shown in FIGS. 2G-1, 2G-2 and 2G-3, after the nanostructures 108′ are formed, a gate structure 142 is formed to surround the nanostructures 108′ and over the isolation structure 110, in accordance with some embodiments. More specifically, the dummy gate structures 118 and the first semiconductor material layers 106 are removed to form nanostructures 108′ with the second semiconductor material layers 108, in accordance with some embodiments.

After the nanostructures 108′ are formed, the gate structure 142 is formed wrapped around the nanostructures 108′. The gate structure 142 wraps around the nanostructures 108′ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layers 144 are oxide layers formed around the nanostructures 108′ and on the top of the base fin structure 105. In some embodiments, the interfacial layers 144 are formed by performing a thermal process.

In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the gate spacer layers 126 and the inner spacer layers 134 in accordance with some embodiments.

In some embodiments, the dielectric constant of the gate dielectric layer 146 of the gate structure 142 is greater than the dielectric constant of the gate spacer layer 126. In some embodiments, the thickness of the gate spacer layer 126 is greater than the thickness of the gate dielectric layer 146.

In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layer 148 is formed on the gate dielectric layer 146. In some embodiments, the gate electrode layer 148 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 148 is formed using chemical vapor deposition (CVD), atomic layer deposition (ALD), electroplating, another applicable method, or a combination thereof. Other conductive layers, such as work function metal layers, may also be formed in the gate structure 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate electrode layer 148 are formed, a planarization process such as CMP or an etch-back process may be performed until the ILD layer 140 is exposed.

It should be noted that the gate structure 142 has a first portion 142a (or outer gate), a second portion 142b (or inner gate) and a third portion 142c. The first portion 142a is formed above the topmost nanostructure 108′ and adjacent to the gate spacer layer 126. The second portion 142b is below the topmost nanostructure 108′ and adjacent to the inner spacer layer 134. The second portion 142b is adjacent to the S/D structure 136. The third portion 142c is formed on the isolation structure 116. In other words, the first portion 142a is interfacing the gate spacer layer 126. The second portion 142b is interfacing the inner spacer layers 134.

The first portion 142a has a first gate length L1 along the first direction (e.g. x-axis). The second portion 142b has a second gate length L2 along the first direction (e.g. x-axis). The third portion 142c has the third gate length L3 along the first direction (e.g. x-axis). In some embodiments, the first gate length L1 of the first portion 142a of the gate structure 142 is greater than the second gate length L2 of the second portion 142b of the gate structure 142. In some embodiments, the third gate length L3 of the third portion 142c of the gate structure 142 is greater than the second gate length L2 of the second portion 142b of the gate structure 142. In some embodiments, the first gate length L1 of the first portion 142a of the gate structure 142 is substantially equal to the third gate length L3 of the third portion 142c of the gate structure 142. In some embodiments, the first gate length L1 is in a range from about 8 nm to about 20 nm. In some embodiments, the second gate length L2 is in a range from about 5 nm to about 18 nm. In some embodiments, the third gate length L3 is in a range from about 8 nm to about 20 nm. In some embodiments, the difference between the first gate length L1 and the second gate length L2 is in a range from about 1 nm to about 10 nm.

If the outer trench for forming the outer gate structure is equal to the inner trench for forming the inner gate structure, the outer trench is easily filled with the gate materials than the inner trench, but the inner trench is not filled with the gate materials. The inner gate structure in the inner trench may have void or seam due to the location of inner trench. In order to reduce the unwanted void or seam formed in the inner gate structure, the width of the outer trench is designed to be greater than the width of the inner trench. Therefore, the width D1 of the outer trench 141 is greater than the width D2 of the inner trench 143 (as shown in FIG. 2F-2). As a result, the first gate length L1 of the first portion 142a of the gate structure 142 is greater than the second gate length L2 of the second portion 142b of the gate structure 142 (as shown in FIG. 2G-2). Therefore, the risk of a void or seam forming in the second portion 142b of the gate structure 142 is reduced and the performance of the semiconductor structure 100a is improved.

FIG. 3 shows a top view of the semiconductor structure 100a along line DD′ of FIG. 2G-2, in accordance with some embodiments.

As shown in FIG. 3, the second portion 142b of the gate structure 142 is between two adjacent S/D structure 136 and between two adjacent inner spacer layers 134. The third portion 142c of the gate structure 142 is between two adjacent gate spacer layers 126. In some embodiments, the third gate length L3 of the third portion 142c of the gate structure 142 is greater than the second gate length L2 of the second portion 142b of the gate structure 142.

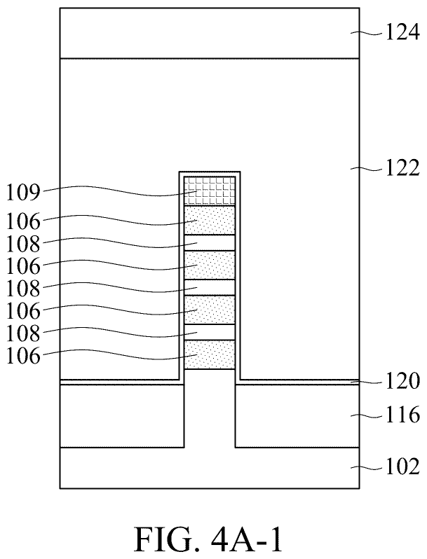

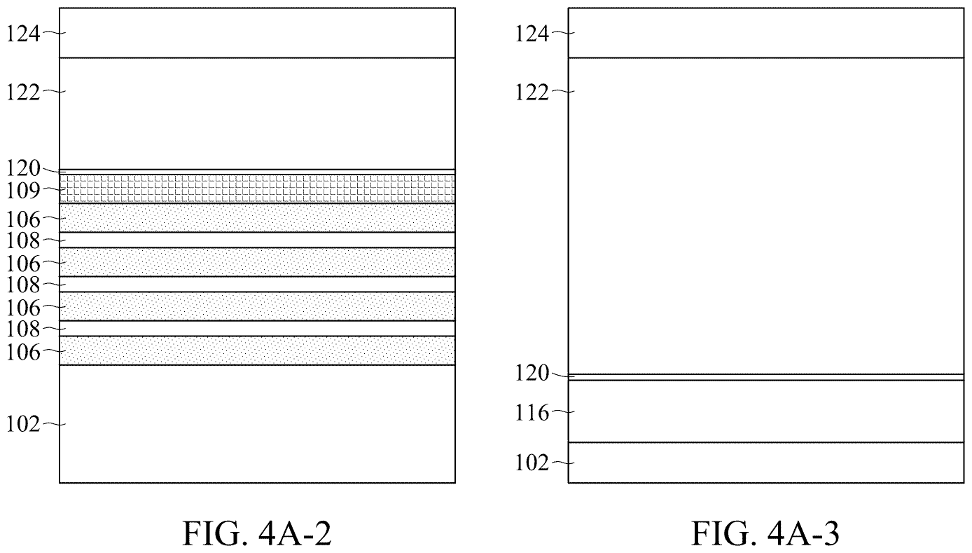

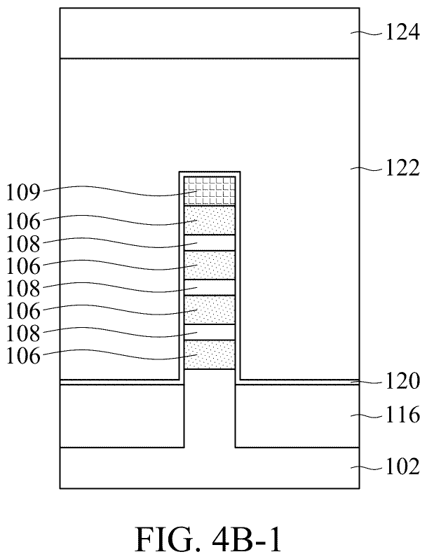

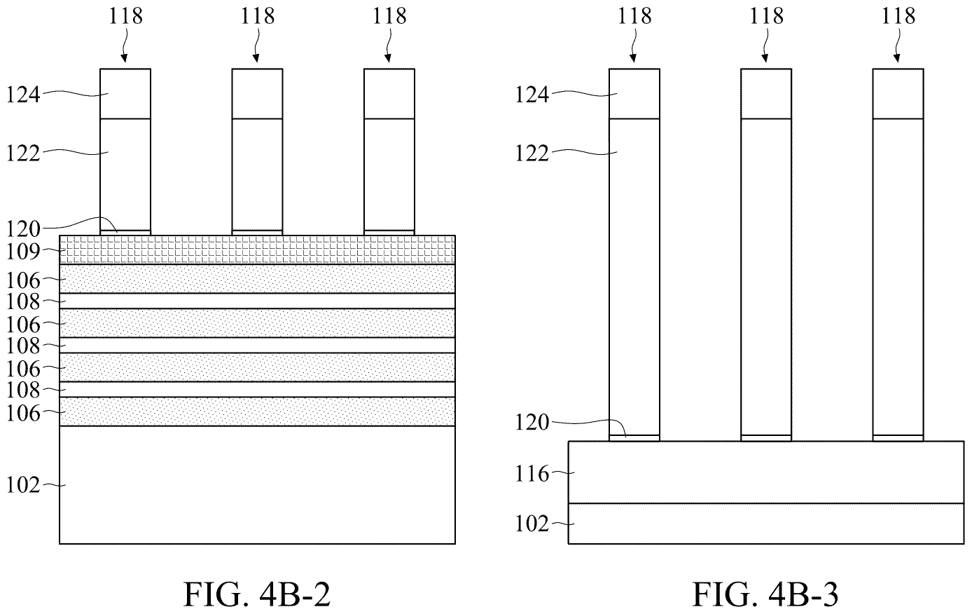

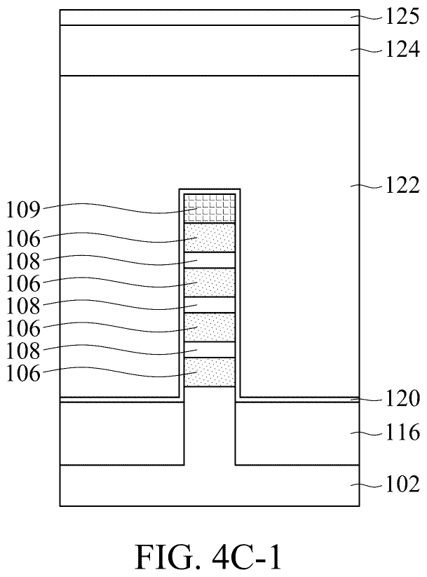

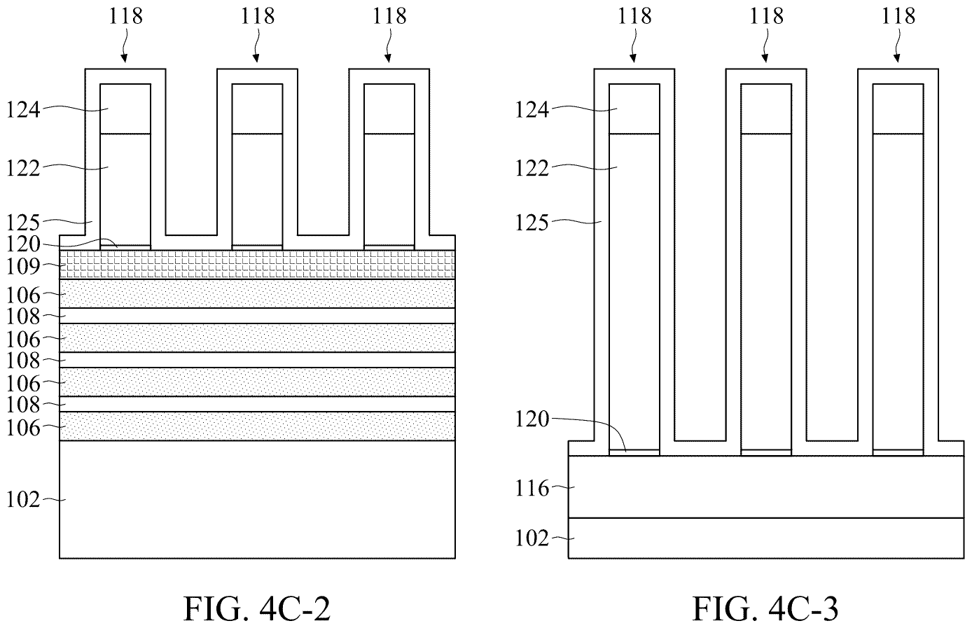

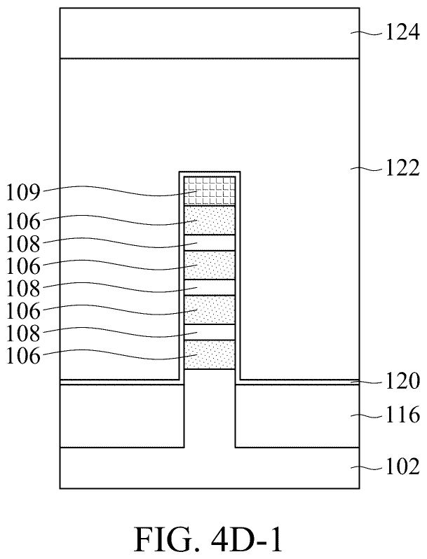

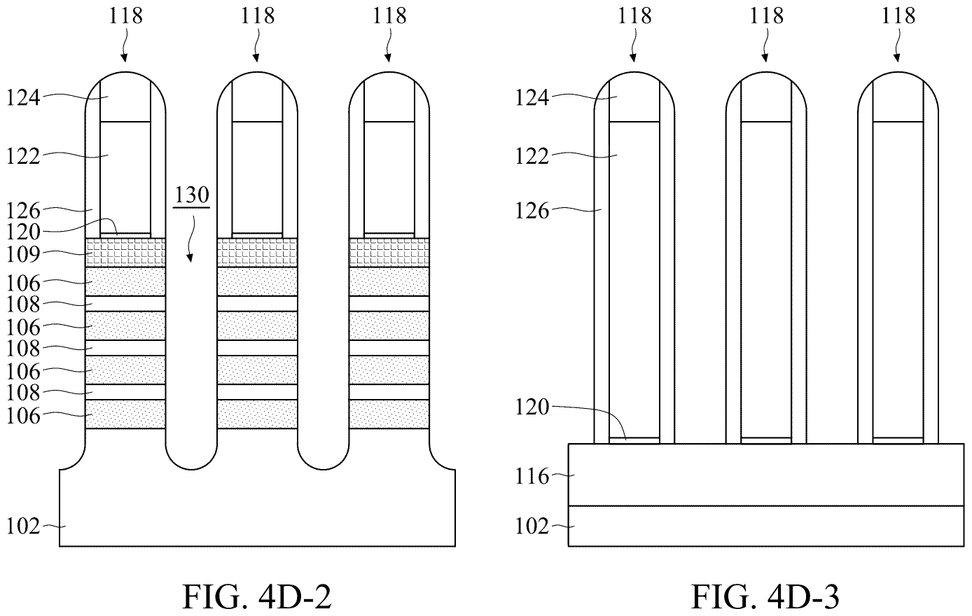

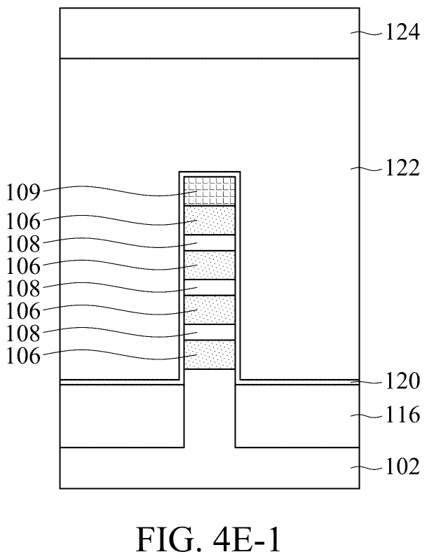

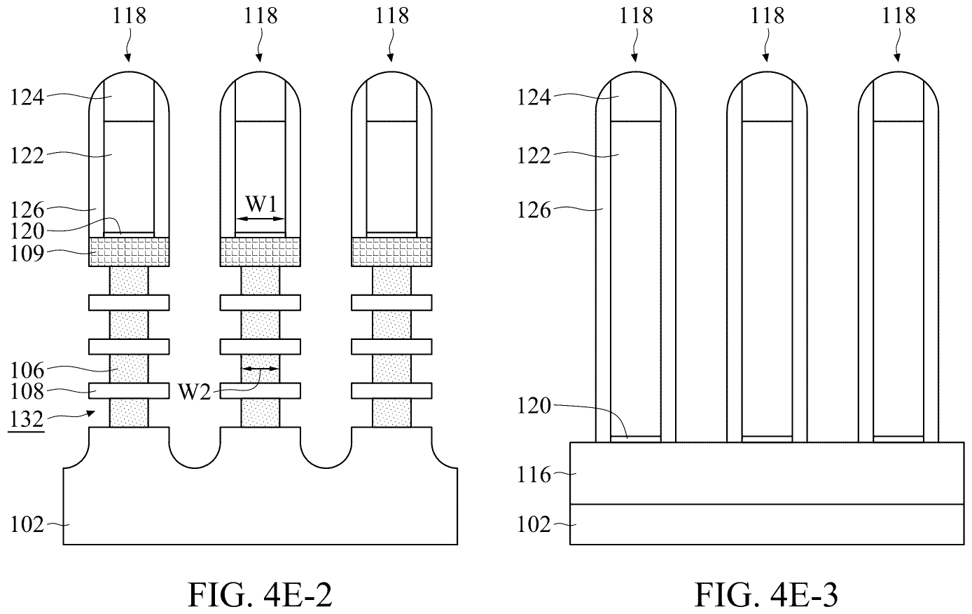

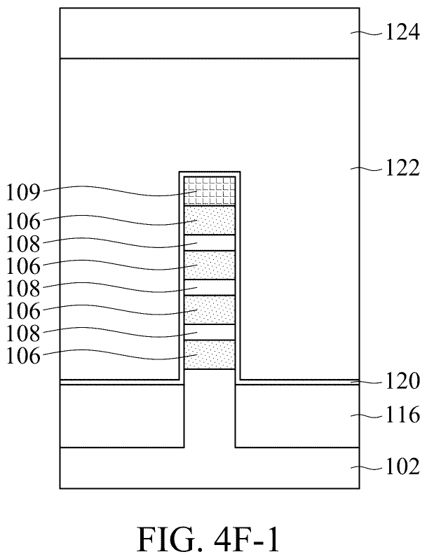

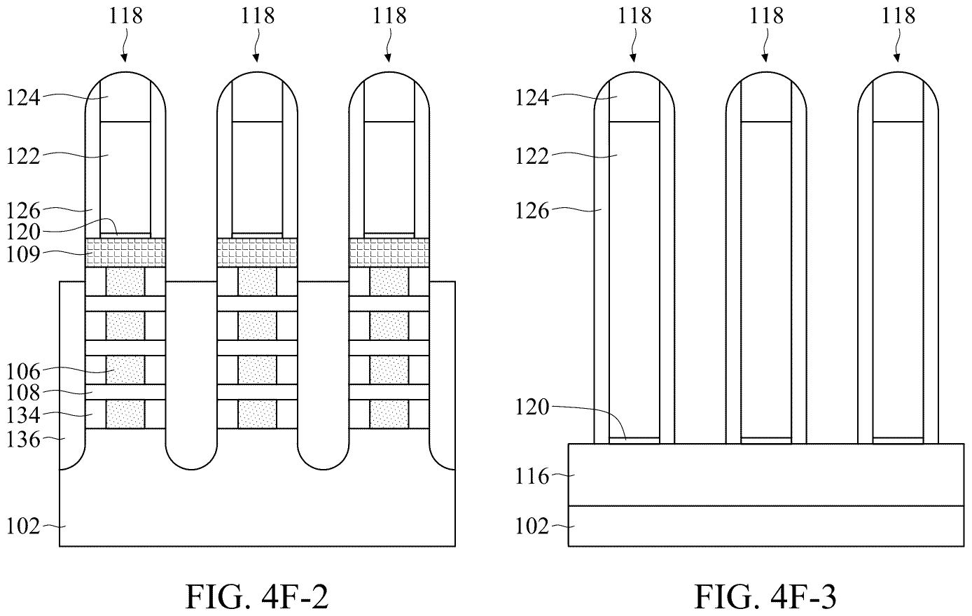

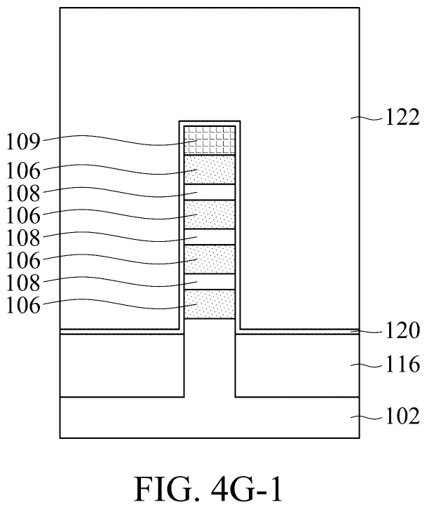

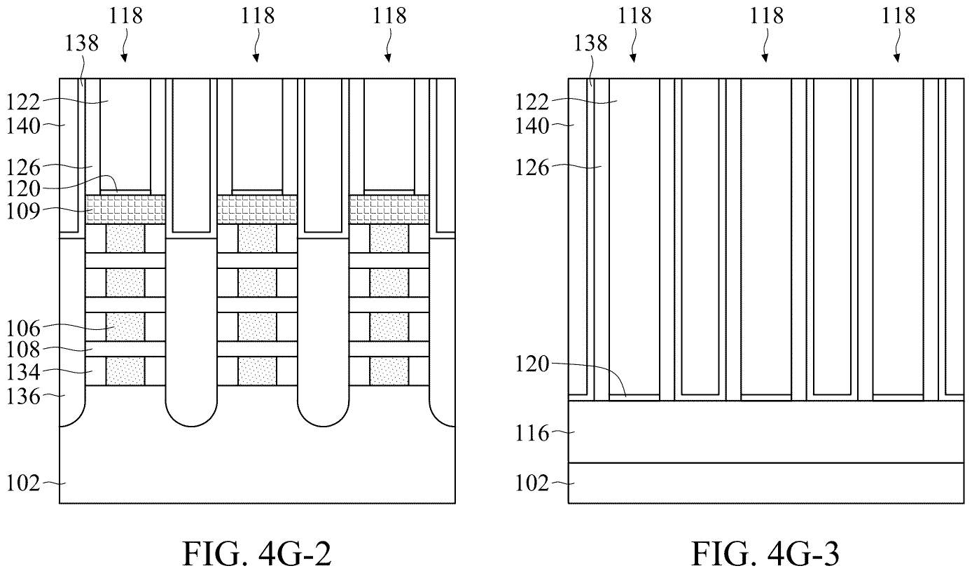

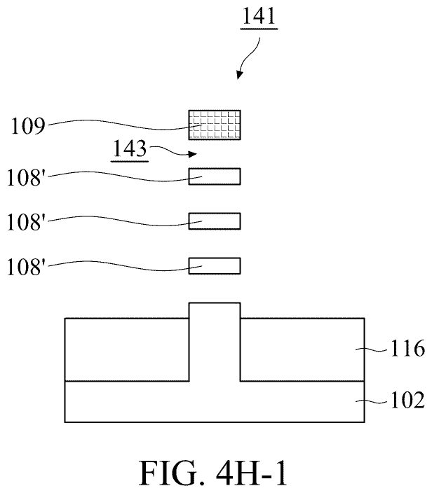

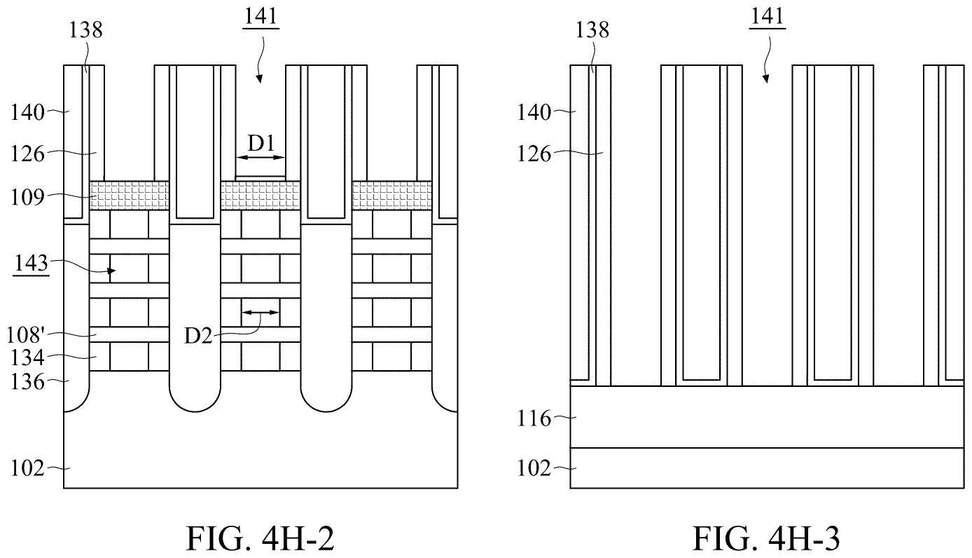

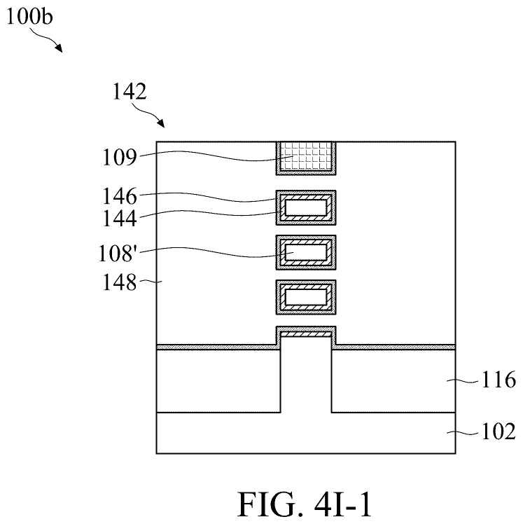

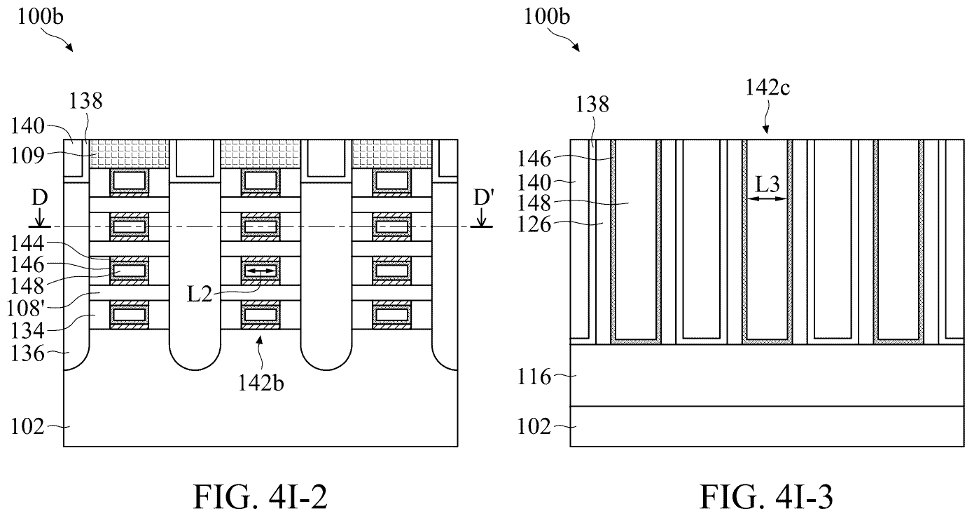

FIGS. 4A-1-4I-1 illustrate cross-sectional representations of a semiconductor structure 100b shown along line A-A′ in FIG. 1E, in accordance with some embodiments. FIGS. 4A-2 to 4I-2 illustrate cross-sectional representations of various stages of manufacturing the semiconductor structure 100b shown along line B-B′ in FIG. 1E, in accordance with some embodiments. FIGS. 4A-3 to 4I-3 illustrate cross-sectional representations of various stages of manufacturing the semiconductor structure 100b shown along line C-C′ in FIG. 1E, in accordance with some embodiments. The semiconductor structure 100b of FIGS. 4A-1-4I-1, 4A-2-4I-2 and 4A-3-4I-3 includes elements that are similar to, or the same as, elements of the semiconductor structure 100a of FIGS. 2A-1-2G-1, 2A-2-2G-2, and 2A-3-2G-3.

As shown in FIGS. 4A-1, 4A-2 and 4A-3, a cap layer 109 is formed over the fin structure 104, in accordance with some embodiments. The cap layer 109 is used to protect the underlying layers and used as an etch stop layer. Next, the dummy gate dielectric layer 120 and the dummy gate electrode layer 122 are formed on the cap layer 109. The hard mask layer 124 is formed over the dummy gate electrode layer 122.

The material of the cap layer 109 may be chosen based on device performance and manufacturing considerations. In some embodiments, the cap layer 109 includes a dielectric material with a dielectric constant (k value) less than 7, such as SiCN, SiOC, SiOCN, or a combination thereof.

Afterwards, as shown in FIGS. 4B-1, 4B-2 and 4B-3, the dummy gate dielectric layer 120 and the dummy gate electrode layer 122 are patterned to form the dummy gate structure 118, in accordance with some embodiments. As a result, the top surfaced of the cap layer 109 is exposed.

Next, as shown in FIGS. 4C-1, 4C-2 and 4C-3, the gate spacer material 125 is formed on the sidewall surface of the dummy gate structure 118, in accordance with some embodiments. More specifically, the gate spacer material 125 is conformally formed on the sidewall surface of the dummy gate structure 118, the top surface of the hard mask layer 124 and the top surface of the isolation structure 116.

Afterwards, as shown in FIGS. 4D-1, 4D-2 and 4D-3, a portion of the gate spacer material 125 is removed to form the gate spacer layers 126, in accordance with some embodiments. More specifically, the gate spacer layers 126 are formed along and covering opposite sidewall surfaces of the dummy gate structure 118. The gate spacer layers 126 are formed on the top surface of the cap layer 109. The outer sidewall surface of the gate spacer layer 126 is substantially aligned with the outer sidewall surface of the cap layer 109.

After the gate spacer layers 126 are formed, the source/drain (S/D) regions of the fin structure 104 are recessed to form the source/drain (S/D) trenches 130. The bottom surface of the S/D trenches 130 is lower than the bottommost surface of the fin structure 104.

Next, as shown in FIGS. 4E-1, 4E-2 and 4E-3, after the source/drain (S/D) trenches 130 are formed, the first semiconductor material layers 106 exposed by the source/drain (S/D) recesses 130 are laterally recessed to form notches 132, in accordance with some embodiments.

As shown in FIG. 4E-2, the dummy gate structure 118 has the first width W1, and the remaining first semiconductor material layer 106 as the second width W2 after the etching process. In some embodiments, the first width W1 of the dummy gate structure 118 is greater than the second width W2 of the remaining first semiconductor material layer 106.

Afterwards, as shown in FIGS. 4F-1, 4F-2 and 4F-3, the inner spacer layers 134 are formed in the notches 132 between the second semiconductor material layers 108, in accordance with some embodiments. The inner spacer layers 134 are configured to separate the source/drain (S/D) structures and the gate structures formed in subsequent manufacturing processes in accordance with some embodiments. The inner spacer layer 134 is between cap layer 109 and the second semiconductor material structure 108 of the fin structure 104.

After the inner spacer layers 134 are formed, the source/drain (S/D) structures 136 are formed in the S/D recesses 130, in accordance with some embodiments. In some embodiments, the source/drain (S/D) structures 136 are epitaxial structures.

In some embodiments, the topmost surface of the S/D structure 136 is lower than the topmost surface of the cap layer 109. In some embodiments, the topmost surface of the S/D structure 136 is lower than the topmost surface of the inner spacer layer 134. In some embodiments, the topmost surface of the S/D structure 136 is higher than the topmost surface of the second semiconductor material layer 108.

Next, as shown in FIGS. 4G-1, 4G-2 and 4G-3, after the source/drain (S/D) structures 136 are formed, the contact etch stop layer (CESL) 138 is conformally formed to cover the S/D structures 136 and the interlayer dielectric (ILD) layer 140 is formed over the contact etch stop layers 138, in accordance with some embodiments.

Afterwards, as shown in FIGS. 4H-1, 4H-2 and 4H-3, the dummy gate structure 118 is removed to form the outer trench 141, in accordance with some embodiments. As a result, the fin structure 104 is exposed by the outer trench 141.

Next, the first semiconductor material layers 106 are removed to form a number of inner trenches 143, in accordance with some embodiments. The nanostructures 108′ with the second semiconductor material layers 108 are formed. The nanostructures 108′ are used as the channel layers of the semiconductor structure 100a. The S/D structures 136 are attached to the nanostructures 108′ (or channel layers). The first fin structure 104 includes the nanostructures 108′.

As shown in FIG. 4H-2, the outer trench 141 has a first width D1, and the inner trench 143 has a second width D2. The first width D1 of the outer trench 141 is greater than the second width D2 of the inner trench 143 since the first width W1 of the dummy gate structure 118 is greater than the second width W2 of the remaining first semiconductor material layer 106 (shown in FIG. 4E-2).

Next, as shown in FIGS. 4I-1, 4I-2 and 4I-3, after the nanostructures 108′ are formed, the gate structure 142 is formed to surround the nanostructures 108′ and over the isolation structure 116, in accordance with some embodiments. More specifically, the dummy gate structures 118 and the first semiconductor material layers 106 are removed to form nanostructures 108′ with the second semiconductor material layers 108, in accordance with some embodiments.

After the nanostructures 108′ are formed, the gate structure 142 is formed wrapped around the nanostructures 108′. The gate structure 142 wraps around the nanostructures 108′ to form gate-all-around transistor structures in accordance with some embodiments. In some embodiments, the gate structure 142 includes the interfacial layer 144, the gate dielectric layer 146, and the gate electrode layer 148. The cap layer 109 is surrounded by the gate dielectric layer 146 and the gate electrode layer 148.

After the interfacial layers 144, the gate dielectric layers 146, and the gate electrode layer 148 are formed, a planarization process such as CMP or an etch-back process may be performed until the cap layer 109 is exposed. A portion of the gate spacer layer 126 above the cap layer 109 is removed to expose the cap layer 109. The inner spacer layer 134 is between cap layer 109 and the nanostrucutre 108′ of the fin structure 104. The cap layer 109 is formed over the nanostrucutre 108′.

After the planarization process, the top surface of the CESL 138 is substantially coplanar with the top surface of the cap layer 109. The top surface of the ILD layer 140 is substantially coplanar with the top surface of the cap layer 109. The top surface of the cap layer 109 is higher than the interface between the CESL 138 and the S/D structure 136. In some other embodiments, as shown in FIG. 4I-3, the top surface of the gate structure 142 is lower than the top surface of the cap layer 109 (in FIG. 4I-2). Since the gate structure 142 and the cap layer 109 are made of different materials, and after the planarization process, the top surface of the gate structure 142 and the top surface of the cap layer 109 are at different level.

It should be noted that the gate structure 142 has the second portion 142b (or inner gate) and the third portion 142c. The second portion 142b is below the cap layer 109 and adjacent to the inner spacer layer 134. The third portion 142c is formed on the isolation structure 116.

The second portion 142b has a second gate length L2 along the first direction (e.g. x-axis). The third portion 142c has the third gate length L3 along the first direction (e.g. x-axis). In some embodiments, the third gate length L3 of the third portion 142c of the gate structure 142 is greater than the second gate length L2 of the second portion 142b of the gate structure 142.

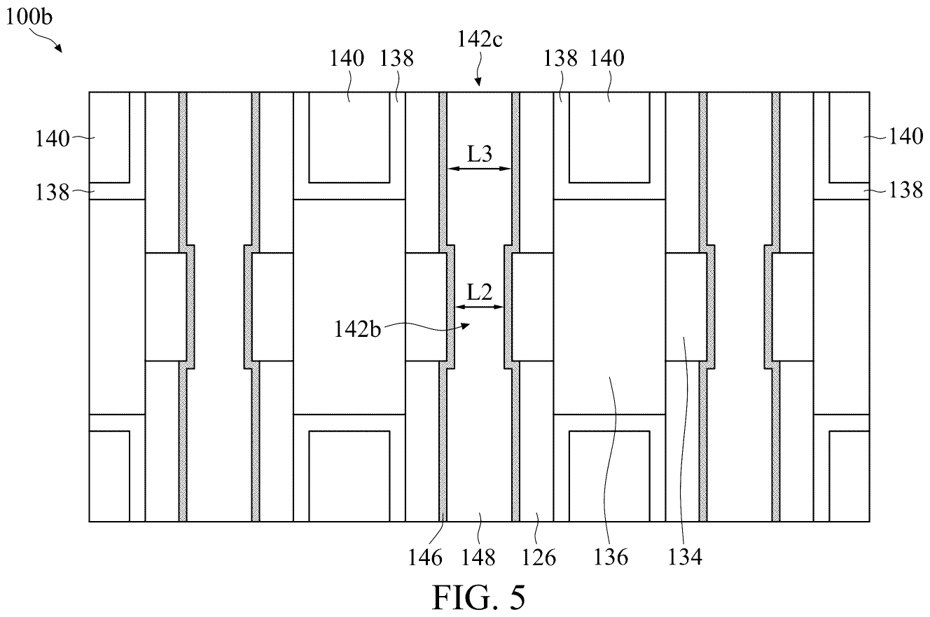

FIG. 5 shows a top view of the semiconductor structure 100b along line DD′ of FIG. 4I-2, in accordance with some embodiments.

As shown in FIG. 5, the second portion 142b of the gate structure 142 is between two adjacent S/D structure 136 and between two adjacent inner spacer layers 134. The third portion 142c of the gate structure 142 is between two adjacent gate spacer layers 126. In some embodiments, the third gate length L3 of the third portion 142c of the gate structure 142 is greater than the second gate length L2 of the second portion 142b of the gate structure 142.

FIGS. 6A-1-6D-1 illustrate cross-sectional representations of a semiconductor structure 100c, shown along line A-A′ in FIG. 1E, in accordance with some embodiments. FIGS. 6A-2-6D-2 illustrate cross-sectional representations of the semiconductor structure 100c, shown along line B-B′ in FIG. 1E, in accordance with some embodiments. FIGS. 6A-3-6D-3 illustrate cross-sectional representations of the semiconductor structure 100c, shown along line C-C′ in FIG. 1E, in accordance with some embodiments. The semiconductor structure 100c of FIGS. 6A-1-6D-1, 6A-2-6D-2 and 6A-3-6D-3 includes elements that are similar to, or the same as, elements of the semiconductor structure 100a of FIGS. 2A-1-2G-1, 2A-2-2G-2, and 2A-3-2G-3 and the semiconductor structure 100b of FIGS. 4A-1-4I-1, 4A-2-4I-2, AND 4A-3-4I-3.

The semiconductor structure 100c in FIGS. 6A-1, 6A-2 and 6A-3 is similar to the semiconductor structure 100a of FIGS. 4G-1, 4G-2 and 4G-3.

As shown in FIGS. 6A-1, 6A-2 and 6A-3, the cap layer 109 is formed over the fin structure 104, in accordance with some embodiments. The cap layer 109 is used to protect the underlying layers and used as an etch stop layer. Next, the dummy gate structure 118 is formed over the cap layer 109. The dummy gate structure 118 includes the dummy gate dielectric layer 120 and the dummy gate electrode layer 122

The gate spacer layers 126 are formed on opposite sidewall surfaces of the dummy gate structure 118. The inner spacer layers 134 are formed adjacent to the first semiconductor material layers 106. The inner spacer layers 134 are between the first semiconductor material layers 106 and the S/D structures 136. The CESL 138 and the ILD layer 140 are formed on the S/D structures 136.

In some embodiments, the topmost source of the cap layer 109 is higher than the topmost surface of the S/D structures 136. In some embodiments, the topmost source of the cap layer 109 is higher than the bottommost surface of the CESL 138. In some embodiments, the interface between the cap layer 109 and the topmost inner spacer layer 134 is higher than the topmost surface of the S/D structures 136.

The dummy gate structure 118 has the first width W1, and the remaining first semiconductor material layer 106 as the second width W2 after the etching process. In some embodiments, the first width W1 of the dummy gate structure 118 is greater than the second width W2 of the remaining first semiconductor material layer 106.

Next, as shown in FIGS. 6B-1, 6B-2 and 6B-3, the dummy gate structure 118 is removed to form the outer trench 141, in accordance with some embodiments. Next, the cap layer 109 is removed. As a result, the fin structure 104 are exposed by the outer trench 141.

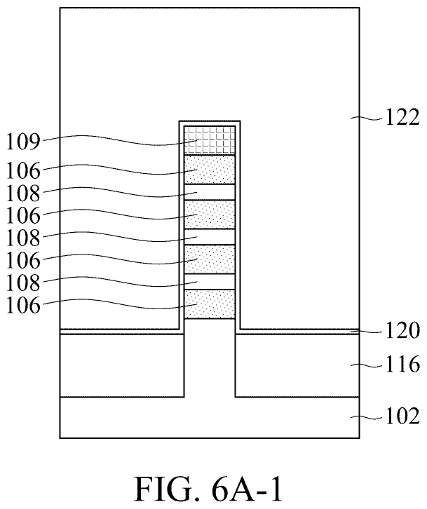

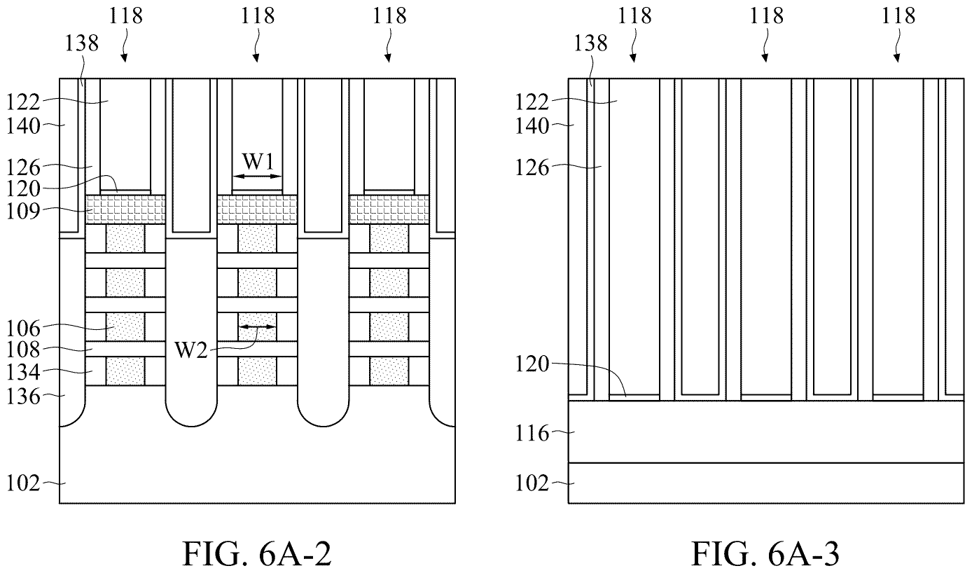

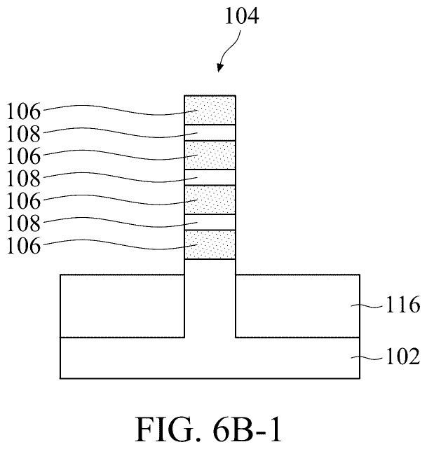

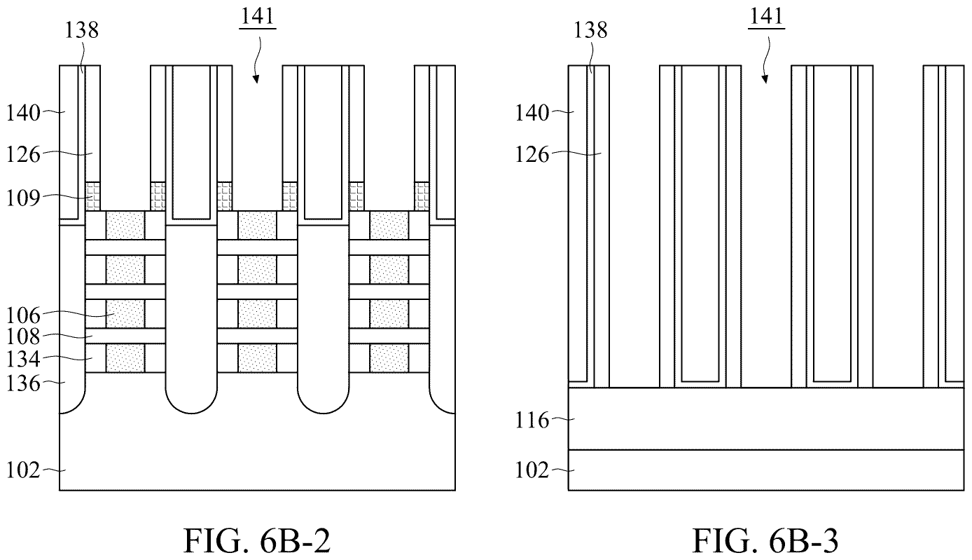

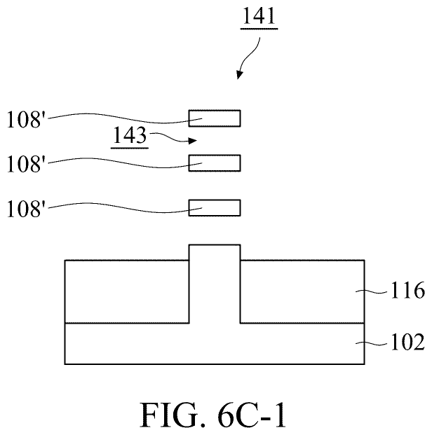

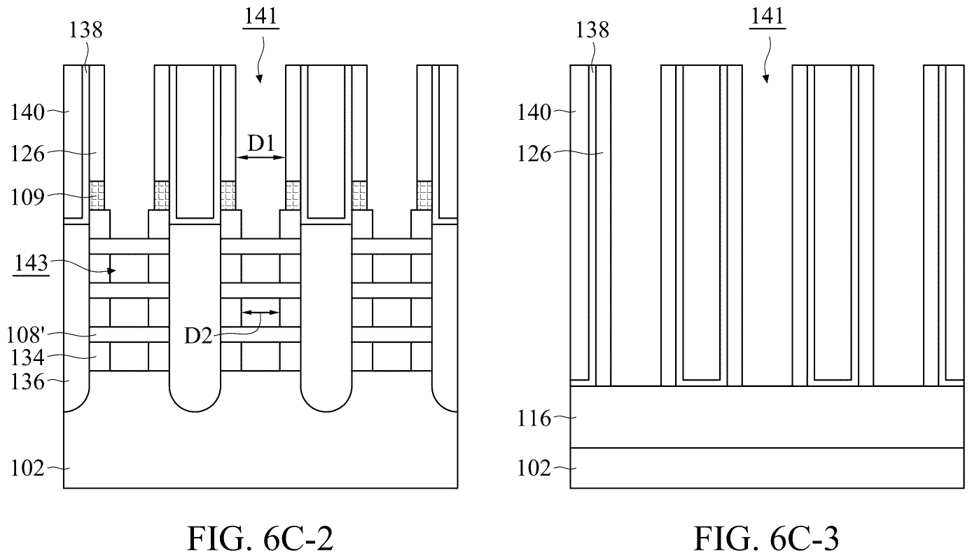

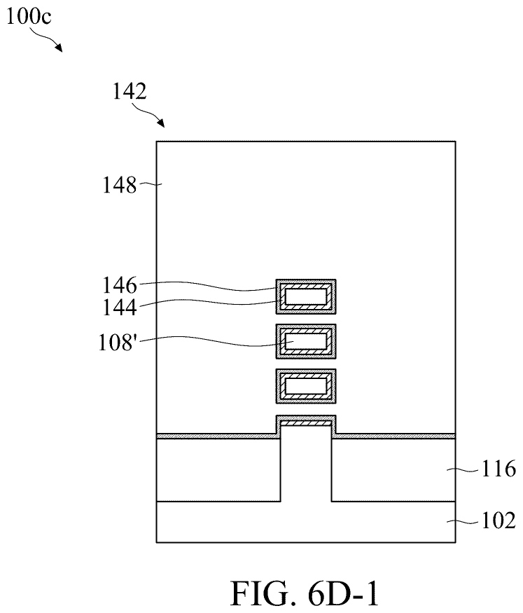

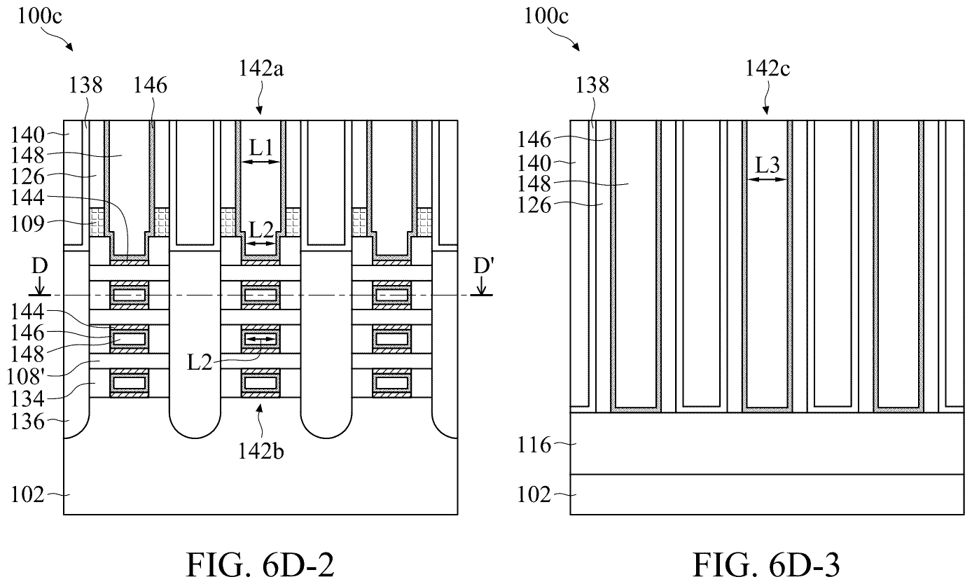

As shown in FIG. 6B-1, there is no mask layer on the fin structure 104. As shown in FIG. 6B-2, a portion of the cap layer 109 not covered by the gate spacer layer 126 is removed to expose the topmost surface of the first semiconductor material layer 106. Another portion of the cap layer 109 remains on the inner spacer layer 1345.

Next, as shown in FIGS. 6C-1, 6C-2 and 6C-3, the first semiconductor material layers 106 are removed to form a number of inner trenches 143, in accordance with some embodiments. The nanostructures 108′ with the second semiconductor material layers 108 are formed. The nanostructures 108′ are used as the channel layers of the semiconductor structure 100a. The S/D structures 136 are attached to the nanostructures 108′ (or channel layers). The fin structure 104 includes the nanostructures 108′.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions. In some other embodiments, the cap layer 109 is removed along with the first semiconductor material layers 106.

It should be noted that, as shown in FIG. 6C-2, the outer trench 141 has the first width D1, and the inner trench 143 has the second width D2. The first width D1 of the outer trench 141 is greater than the second width D2 of the inner trench 143 since the first width W1 of the dummy gate structure 118 is greater than the second width W2 of the remaining first semiconductor material layer 106 (shown in FIG. 6A-2).

Next, as shown in FIGS. 6D-1, 6D-2 and 6D-3, after the nanostructures 108′ are formed, the gate structure 142 is formed to surround the nanostructures 108′ and over the isolation structure 110, in accordance with some embodiments. More specifically, the dummy gate structures 118 and the first semiconductor material layers 106 are removed to form nanostructures 108′ with the second semiconductor material layers 108, in accordance with some embodiments.

After the nanostructures 108′ are formed, the gate structure 142 is formed wrapped around the nanostructures 108′. The gate structure 142 wraps around the nanostructures 108′ to form gate-all-around transistor structures in accordance with some embodiments. In some embodiments, the gate structure 142 includes the interfacial layer 144, the gate dielectric layer 146, and the gate electrode layer 148.

After the interfacial layers 144, the gate dielectric layers 146, and the gate electrode layer 148 are formed, a planarization process such as CMP or an etch-back process may be performed until the cap layer 109 is exposed.

After the planarization process, the top surface of the cap layer 109 and the top surface of the gate structure 142 are exposed. The cap layer 109 is between the gate structure 142 and the CESL 138. The cap layer 109 is interfacing the CESL 138.

It should be noted that the gate structure 142 has the first portion 142a (or outer gate), the second portion 142b (or inner gate) and the third portion 142c. The first portion 142a is formed above the topmost nanostructure 108′ and adjacent to the cap layer 109. The first portion 142a of the gate structure 142 has a T-shaped structure with a top portion and a bottom portion. The top portion of the first portion 142a of the gate structure 142 has the first gate length L1 and the bottom portion of the first portion 142a of the gate structure 142 has the second gate length L2. In some embodiments, the first gate length L1 is greater than the second gate length L2.

The second portion 142b is below the topmost nanostructure 108′ and adjacent to the inner spacer layer 134 and adjacent to the S/D structure 136. The third portion 142c is formed on the isolation structure 116. The second portion 142b has the second gate length L2 along the first direction (e.g. x-axis). The third portion 142c has the third gate length L3 along the first direction (e.g. x-axis). In some embodiments, the first gate length L1 of the first portion 142a of the gate structure 142 is greater than the second gate length L2 of the second portion 142b of the gate structure 142. In some embodiments, the third gate length L3 of the third portion 142c of the gate structure 142 is greater than the second gate length L2. In some embodiments, the first gate length L1 of the first portion 142a of the gate structure 142 is substantially equal to the third gate length L3 of the third portion 142c of the gate structure 142.

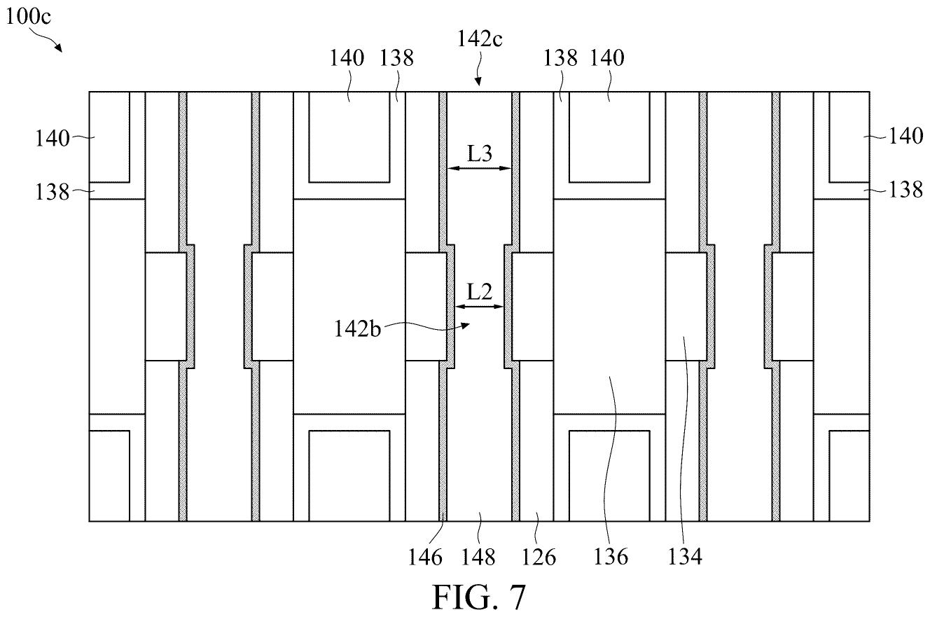

FIG. 7 shows a top view of the semiconductor structure 100b along line DD′ of FIG. 6D-2, in accordance with some embodiments.

As shown in FIG. 7, the second portion 142b of the gate structure 142 is between two adjacent S/D structure 136 and between two adjacent inner spacer layers 134. The third portion 142c of the gate structure 142 is between two adjacent gate spacer layers 126. In some embodiments, the third gate length L3 of the third portion 142c of the gate structure 142 is greater than the second gate length L2 of the second portion 142b of the gate structure 142.

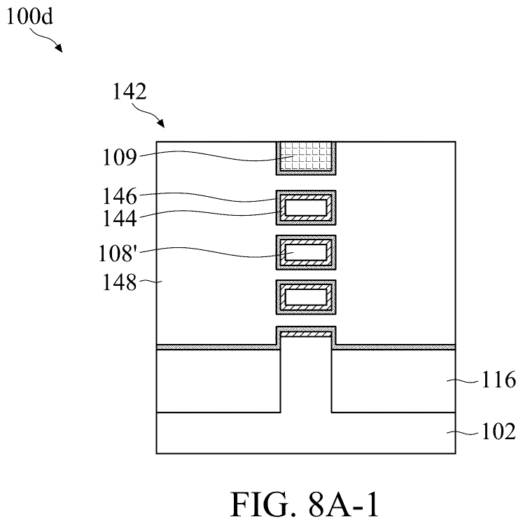

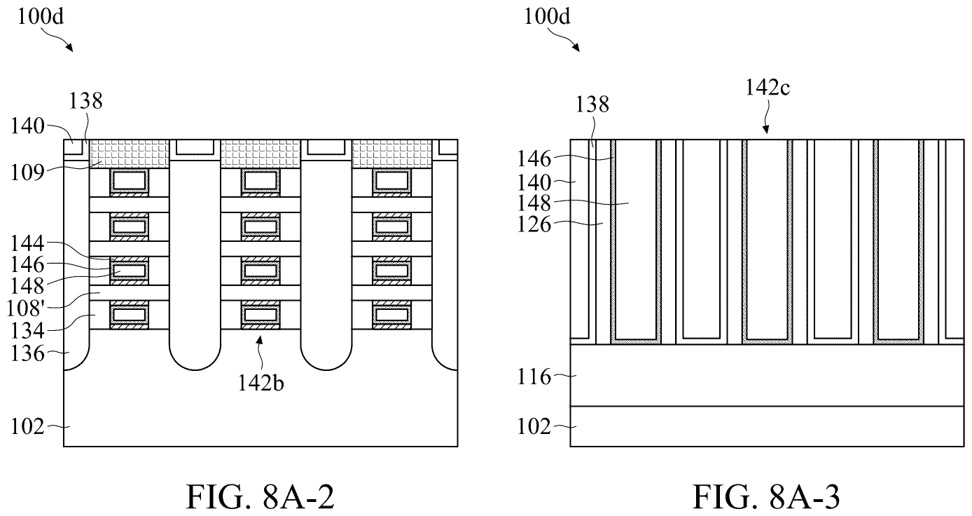

FIGS. 8A-1, 8A-2 and 8A-3 illustrate a cross-sectional view of a semiconductor structure 100d, in accordance with some embodiments. The semiconductor structure 100d of FIGS. 8A-1, 8A-2 and 8A-3 include elements that are similar to, or the same as, elements of the semiconductor structure 100b of FIG. 4I-2, the difference between FIGS. 8A-1, 8A-2 and 8A-3 and FIGS. 4I-1, 4I-2 and 4I-3 is that the top surface of the S/D structure 136 is higher than the topmost surface of the inner spacer layer 134. The top surface of the S/D structure 136 is lower than the top surface of the cap layer 109. The interface between the S/D structure 136 and the CESL 138 is higher than the topmost surface of the inner spacer layer 134. The interface between the S/D structure 136 and the CESL 138 is higher than the topmost surface of the nanostructure 108′. In some other embodiments, the top surface of the S/D structure 136 is substantially coplanar with the topmost surface of the inner spacer layer 134.

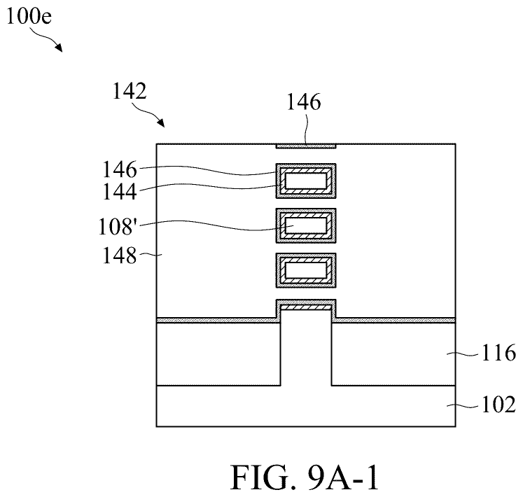

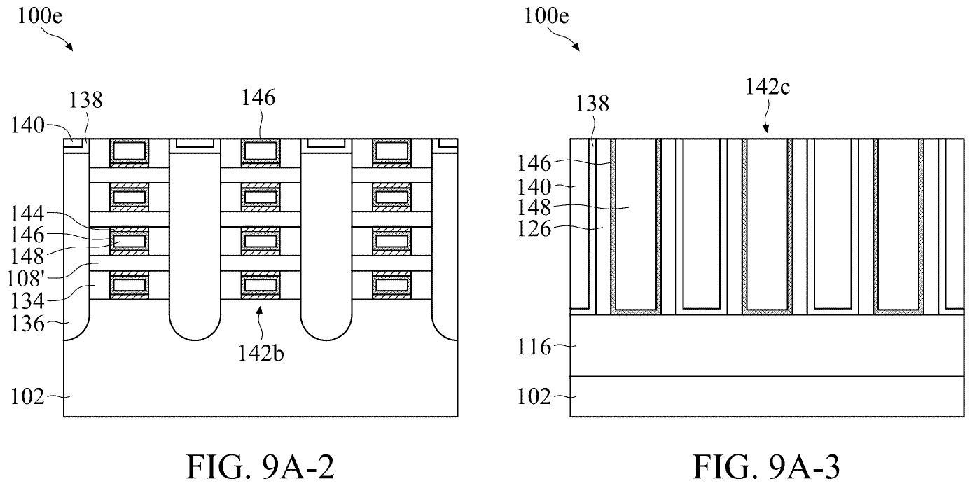

FIGS. 9A-1, 9A-2 and 9A-3 illustrate cross-sectional representations of a semiconductor structure 100e, in accordance with some embodiments. The semiconductor structure 100e of FIGS. 9A-1, 9A-2 and 9A-3 includes elements that are similar to, or the same as, elements of the semiconductor structure 100b of FIGS. 4I-1, 4I-2 and 4I-3, the difference between FIGS. 9A-1, 9A-2 and 9A-3 and FIGS. 4I-1, 4I-2 and 4I-3 is that the cap layer 109 is removed to expose the gate dielectric layer 146 of the gate structure 142.

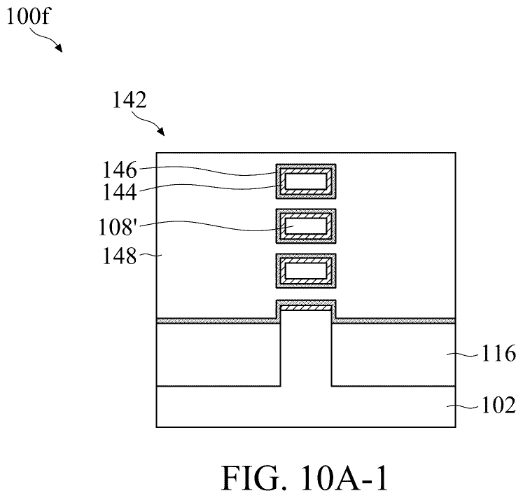

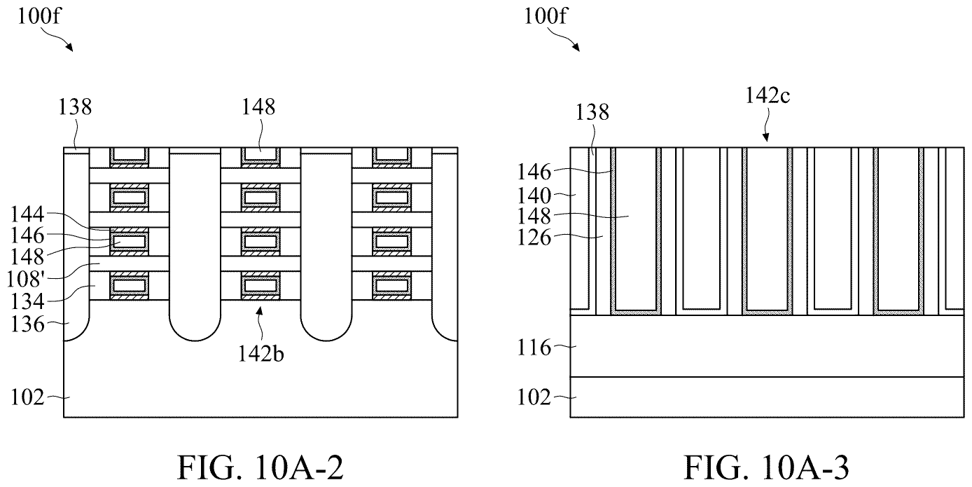

FIGS. 10A-1, 10A-2 and 10A-3 illustrate cross-sectional representations of a semiconductor structure 100f, in accordance with some embodiments. The semiconductor structure 100f of FIGS. 10A-1, 10A-2 and 10A-3 includes elements that are similar to, or the same as, elements of the semiconductor structure 100b of FIGS. 4I-1, 4I-2 and 4I-3, the difference between FIGS. 10A-1, 10A-2 and 10A-3 and FIGS. 4I-1, 4I-2 and 4I-3 is that the topmost gate electrode layer 148 of the gate structure 142 is exposed. The topmost gate dielectric layer 146 of the gate structure 142 is removed to expose the topmost gate electrode layer 148 of the gate structure 142.

Since the topmost gate dielectric layer 146 of the gate structure 142 is removed, the height of the topmost portion of the gate structure 142 is lower than the height of the bottommost portion of the gate structure 142.

It should be appreciated that the semiconductor structures 100a to 100f having the outer gate length is greater than the inner gate length. In some embodiments, the first gate length L1 of the first portion 142a of the gate structure 142 is greater than the second gate length L2 of the second portion 142b of the gate structure 142. In some embodiments, the third gate length L3 of the third portion 142b of the gate structure 142 is greater than the second gate length L2 of the second portion 142b of the gate structure 142.

In some embodiments, the first gate portion 142a of the gate structure 142 has a T shaped structure with the top portion having the first gate length L1 and the bottom portion having the second gate length L2, and the first gate length L1 is greater than the second gate length L2. In some embodiments, the cap layer 109 above the nanostructure 108′ is removed. In some embodiments, the gate dielectric layer 146 of the gate structure 142 is exposed. In some embodiments, the gate electrode layer 148 of the gate structure 142 is exposed. By forming the different gate lengths at different regions, the risk of a void or seam forming in the second portion 142b of the gate structure 142 is greatly reduced. Therefore, the performance of the semiconductor structure 100a-100f is improved by the shorter inner gate length.

It should be noted that the gate structure 142 has different gate lengths in different regions, and the inner gate length is smaller than the outer gate length. Therefore, the risk of a void or seam forming in the second portion 142b of the gate structure 142 is reduced and the performance of the semiconductor structure 100a-100f is improved.

It should be noted that same elements in FIGS. 1A to 10A-3 may be designated by the same numerals and may include similar or the same materials and may be formed by similar or the same processes; therefore such redundant details are omitted in the interest of brevity. In addition, although FIGS. 1A to 10A-3 are described in relation to the method, it will be appreciated that the structures disclosed in FIGS. 1A to 10A-3 are not limited to the method but may stand alone as structures independent of the method. Similarly, although the methods shown in FIGS. 1A to 10A-3 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes an isolation structure formed over a substrate. A number of nanostructures (channel layers) are formed over the substrate. A gate structure is formed on the nanostructures, and a gate spacer layer formed on a sidewall of the gate structure. The gate structure includes a first portion (or outer gate), a second portion (or inner gate) and a third portion. The first portion is formed over the topmost nanostructure, a second portion is below a topmost nanostructure, and a third portion is formed on the isolation structure. The first portion (or outer gate) has a first gate length, the second portion (or inner gate) has a second gate length, and the third portion has a third gate length. The first gate length of the first portion (or outer gate) is greater than the second gate length of the second portion (or inner gate), and the third gate length is greater than the second gate length. Therefore, the risk of a void or seam forming in the second portion (or inner gate) of the gate structure is reduced and the performance of the semiconductor structure is improved.

In some embodiments, a semiconductor structure is provided. The semiconductor structure includes a plurality of nanostructures formed over a substrate, and an isolation structure formed over the substrate. The semiconductor structure includes a gate structure formed on the nanostructures, and the gate structure comprises a gate dielectric layer and a gate electrode over the gate dielectric layer. The semiconductor structure includes a first gate spacer layer formed on a sidewall of the gate structure, and a dielectric constant of the gate dielectric layer is greater than a dielectric constant of the first gate spacer layer. The gate structure includes a first portion on the isolation structure and a second portion below a topmost nanostructure, and the first portion has a first gate length, the second portion has a second gate length, and the first gate length is greater than the second gate length.

In some embodiments, a semiconductor structure is provided. The semiconductor structure includes a plurality of nanostructures formed over a substrate, and a cap layer formed over the nanostructures. The semiconductor structure includes a gate structure formed on the nanostructures, and the gate structure comprises a gate dielectric layer. The semiconductor structure includes a first gate spacer layer formed adjacent to the gate structure, and a thickness of the first gate spacer layer is greater than a thickness of the gate dielectric layer. The semiconductor structure includes a first S/D structure formed adjacent to the gate structure, and the gate structure has a first portion adjacent to the first gate spacer layer and a second portion adjacent to the first S/D structure. The first portion has a first gate length, the second portion has a second gate length, and the first gate length is greater than the second gate length.

In some embodiments, a method for forming a semiconductor structure is provided. The method includes forming a fin structure over a substrate, and the fin structure includes first semiconductor material layers and second semiconductor material layers alternately stacked. The method includes forming a dummy gate structure over the fin structure, and the dummy gate structure has a first width. The method includes removing a portion of the fin structure to form a trench, and removing a portion of the first semiconductor material layers to removing a portion of the first semiconductor material layers to form a remaining first semiconductor material layer has a second width, and the first width is greater than the second width. The method includes forming an S/D structure in the trench. The method includes removing the dummy gate structure, and removing the second semiconductor material layers to form nanostructures. The method includes forming a gate structure on the nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of nanostructures formed over a substrate;
an isolation structure formed over the substrate;
a gate structure formed on the nanostructures, wherein the gate structure comprises a gate dielectric layer and at least one metal layer over the gate dielectric layer; and
a first gate spacer layer formed on a sidewall of the gate structure, wherein a dielectric constant of the gate dielectric layer is greater than a dielectric constant of the first gate spacer layer,
the gate structure comprises a first portion on the isolation structure and a second portion below a topmost nanostructure, wherein the first portion has a first gate length, the second portion has a second gate length, and the first gate length is greater than the second gate length.

2. The semiconductor structure as claimed in claim 1, further comprising:
a cap layer formed over the topmost nanostructure.

3. The semiconductor structure as claimed in claim 2, further comprising:
an inner spacer layer formed over the topmost nanostructure, wherein the inner spacer layer is between the cap layer and the topmost nanostructure.

4. The semiconductor structure as claimed in claim 2, wherein the first gate spacer layer is formed on the cap layer.

5. The semiconductor structure as claimed in claim 1, wherein the gate structure has a T-shaped structure.

6. The semiconductor structure as claimed in claim 1, further comprising:
a second gate spacer layer formed on another sidewall surface of the gate structure; and
a first inner spacer layer and a second inner spacer layer formed on opposite sidewall surfaces of the gate structure, wherein there is a first distance between the first gate spacer layer and the second gate spacer layer, and a second distance between the first inner spacer layer and the second inner spacer layer, and the first distance is greater than the second distance.

7. The semiconductor structure as claimed in claim 1, further comprising:
a cap layer formed over the topmost nanostructure; and
an S/D structure formed adjacent to the gate structure, wherein a top surface of the S/D structure is lower than a top surface of the cap layer.

8. The semiconductor structure as claimed in claim 7, further comprising:
an etch stop layer formed on the S/D structure, wherein a top surface of the etch stop layer is coplanar with a top surface of the cap layer.

9. The semiconductor structure as claimed in claim 8, wherein the cap layer is between the etch stop layer and the gate structure.

10. A semiconductor structure, comprising:
a plurality of nanostructures formed over a substrate;
a cap layer formed over the nanostructures;
a gate structure formed on the nanostructures, wherein the gate structure comprises a gate dielectric layer;
a first gate spacer layer formed adjacent to the gate structure, wherein a thickness of the first gate spacer layer is greater than a thickness of the gate dielectric layer; and
a first S/D structure formed adjacent to the gate structure, wherein the gate structure has a first portion adjacent to the first gate spacer layer and a second portion adjacent to the first S/D structure, wherein the first portion has a first gate length, the second portion has a second gate length, and the first gate length is greater than the second gate length.

11. The semiconductor structure as claimed in claim 10, wherein the gate structure has a T-shaped structure with a top portion and a bottom portion, the top portion is interfacing the cap layer and the bottom portion is interfacing a first inner spacer layer, and a width of the top portion is greater than a width of the bottom portion.

12. The semiconductor structure as claimed in claim 11, wherein the width of the bottom portion is equal to the second gate length.

13. The semiconductor structure as claimed in claim 10, further comprising:
an S/D structure formed adjacent to the gate structure, wherein a top surface of the S/D structure is lower than a top surface of the cap layer.

14. The semiconductor structure as claimed in claim 13, further comprising:
an etch stop layer formed on the S/D structure, wherein the etch stop layer is interfacing the cap layer.

15. The semiconductor structure as claimed in claim 14, wherein the gate structure has a topmost portion and a bottommost portion, and a height of the topmost portion is smaller than a height of the bottommost portion.

16. The semiconductor structure as claimed in claim 10, further comprising:
a second gate spacer layer formed adjacent to the gate structure;
a first inner spacer layer formed adjacent to the gate structure; and
a second inner spacer layer formed adjacent to the gate structure, wherein there is a first distance between the first gate spacer layer and the second gate spacer layer, and a second distance between the first inner spacer layer and the second inner spacer layer, and the first distance is greater than the second distance.

17. A method for forming a semiconductor structure, comprising:
forming a fin structure over a substrate, wherein the fin structure comprises first semiconductor material layers and second semiconductor material layers alternately stacked;
forming a dummy gate structure over the fin structure, wherein the dummy gate structure has a first width;
removing a portion of the fin structure to form a trench;
removing a portion of the first semiconductor material layers to form a remaining first semiconductor material layer has a second width, and the first width is greater than the second width;
forming an S/D structure in the trench;
removing the dummy gate structure;
removing the second semiconductor material layers to form nanostructures; and
forming a gate structure on the nanostructures.

18. The method for forming the semiconductor structure as claimed in claim 17, further comprising:
forming a cap layer over the fin structure, wherein the cap layer is formed over a topmost nanostructure.

19. The method for forming the semiconductor structure as claimed in claim 18, further comprising:
removing a portion of the first semiconductor material layers to form notches;
forming an inner spacer layer in the notches; and
removing a first portion of the cap layer, wherein a second portion of the cap layer remains on the inner spacer layer.

20. The method for forming the semiconductor structure as claimed in claim 17, further comprising:
forming a cap layer over the fin structure
forming a gate spacer layer adjacent to the dummy gate structure, wherein the gate spacer layer is over the cap layer; and
removing the gate spacer layer to expose the cap layer.
